(19) United States
(12) Patent Application Publication
(10) Pub. No.: US 2019/0393393 A1
(43) Pub. Date: Dec. 26, 2019

(54) THERMOELECTRIC CONVERSION LAYER, COMPOSITION FOR FORMING THERMOELECTRIC CONVERSION LAYER, THERMOELECTRIC CONVERSION ELEMENT, AND THERMOELECTRIC CONVERSION MODULE

(71) Applicant: FUJIFILM Corporation, Tokyo (JP)

(72) Inventors: Hiroki Sugiura, Ashigara-kami-gun (JP); Naoyuki Hayashi, Ashigara-kami-gun (JP); Kimiatsu Nomura, Ashigara-kami-gun (JP)

(73) Assignee: FUJIFILM Corporation, Tokyo (JP)

(21) Appl. No.: 16/552,186

(22) Filed: Aug. 27, 2019

Related U.S. Application Data
(63) Continuation of application No. PCT/JP2018/007526, filed on Feb. 28, 2018.

(30) Foreign Application Priority Data
Feb. 28, 2017 (JP) 2017-037253

(51) Int. Cl. H01L 35/22; H01L 35/24; H01L 35/04

(52) U.S. Cl. CPC H01L 35/22; H01L 35/04; H01L 35/24

(57) ABSTRACT

An object of the present invention is to provide a thermoelectric conversion layer having excellent thermoelectric conversion performances (particularly, a power factor and a figure of merit Z). Another object of the present invention is to provide a composition for forming a thermoelectric conversion layer that is used for forming the thermoelectric conversion layer, and a thermoelectric conversion element and a thermoelectric conversion module including the thermoelectric conversion layer.

The thermoelectric conversion layer according to an embodiment of the present invention is a thermoelectric conversion layer containing single-layer carbon nanotubes and a dopant, in which the single-layer carbon nanotubes contain semiconducting single-layer carbon nanotubes at a ratio equal to or higher than 95% and have a G/D ratio equal to or higher than 40, and the dopant is an organic dopant having a non-onium salt structure and has an oxidation-reduction potential equal to or higher than 0 V with respect to a saturated calomel electrode.

### CROSS-REFERENCE TO RELATED APPLICATIONS

This application is a Continuation of PCT International Application No. PCT/JP2018/007526 filed on Feb. 28, 2018, which claims priority under 35 U.S.C. § 119(a) to Japanese Patent Application No. 2017-037253 filed on Feb. 28, 2017. The above application is hereby expressly incorporated by reference, in its entirety, into the present application.

### BACKGROUND OF THE INVENTION

### 1. Field of the Invention

The present invention relates to a thermoelectric conversion layer, a composition for forming a thermoelectric conversion layer, a thermoelectric conversion element, and a thermoelectric conversion module.

### 2. Description of the Related Art

Thermoelectric conversion materials that enable the interconversion of thermal energy and electric energy are used in power generating elements generating electric power from heat or thermoelectric conversion elements such as a Peltier element. Thermoelectric conversion elements can convert thermal energy directly into electric power, do not require a moving portion, and are used in, for example, wristwatches operating by body temperature, power supplies for backwoods, aerospace power supplies, and the like.

As thermoelectric conversion materials, carbon materials represented by carbon nanotubes (hereinafter, referred to as “CNT” as well) have been suggested.

In recent years, in order to improve the performance of instruments using thermoelectric conversion elements, further improvement of the thermoelectric conversion performance of the thermoelectric conversion elements has been required. Accordingly, an examination is being performed regarding a method for preparing a thermoelectric conversion element by using, among CNT, single-layer CNT (hereinafter, referred to as “single-layer CNT with a high semiconductor ratio” as well) containing semiconducting CNT, which have a high Seebeck coefficient as one of the thermoelectric conversion performances, at a high concentration.

Generally, CNT express a high thermoelectric conversion performance (particularly, a power factor (hereinafter, referred to as “PF” as well)) by being doped with the oxygen in the atmosphere. However, in a case where CNT contain a large amount of semiconducting CNT, the oxygen doping becomes insufficient, and unfortunately, it is difficult to obtain an appropriate thermoelectric conversion performance (particularly, a power factor) in the atmosphere.

In order to solve the problem, for instance, Example in JP2016-015361A discloses a technique of electrochemically doping single-layer CNT containing semiconducting CNT at a high concentration by using trimethyl propyl ammonium bis(trifluoromethanesulfonyl)imide which is an ionic liquid.

Meanwhile, Applied Physics Express 9. 025102 (2016) discloses a technique of doping single-layer CNT containing semiconducting CNT at a high concentration by using nitric acid.

### SUMMARY OF THE INVENTION

Under these circumstances, based on JP2016-015361A, the inventors of the present invention prepared a thermoelectric conversion layer, which contains single-layer CNT containing semiconducting CNT at a high concentration and trimethyl propyl ammonium bis(trifluoromethanesulfonyl)imide, and performed various examinations.

As a result, it has been revealed that the prepared thermoelectric conversion layer does not necessarily satisfy the currently required thermoelectric conversion performances (particularly, a power factor and a figure of merit Z).

Furthermore, the inventors of the present invention prepared a thermoelectric conversion layer by the aforementioned method by using nitric acid as a dopant, and examined the performance thereof. As a result, it has been revealed that the thermoelectric conversion layer does not necessarily satisfy the currently required thermoelectric conversion performances (particularly, a power factor and a figure of merit Z) as described above. In addition, it has been confirmed that because nitric acid is a strong acid and volatile, the thermoelectric conversion layer formed using nitric acid as a dopant results in a large variation in thermoelectric conversion performances (particularly, a figure of merit Z) and has poor temporal stability.

Given the aforementioned circumstances, the present invention aims to provide a thermoelectric conversion layer having excellent thermoelectric conversion performances (particularly, a power factor and a figure of merit Z).

Another object of the present invention is to provide a composition for forming a thermoelectric conversion layer used for forming the thermoelectric conversion layer.

The present invention also aims to provide a thermoelectric conversion element and a thermoelectric conversion module comprising the thermoelectric conversion layer.

In order to achieve the aforementioned objects, the inventors of the present invention conducted an intensive examination. As a result, the inventors have found that the objects can be achieved by a thermoelectric conversion layer containing single-layer CNT exhibiting predetermined characteristics and an organic dopant (particularly, a compound having a quinoid structure) having a non-onium salt structure that has an oxidation-reduction potential equal to or higher than a predetermined value, and accomplished the present invention.

That is, the inventors have found that the aforementioned objects can be achieved by the following constitution.

[1] A thermoelectric conversion layer containing single-layer carbon nanotubes and a dopant, in which the single-layer carbon nanotubes contain semiconducting single-layer carbon nanotubes at a ratio equal to or higher than 95% and have a G/D ratio equal to or higher than 40, and the dopant is an organic dopant having a non-onium salt structure and has an oxidation-reduction potential equal to or higher than 0 V with respect to a saturated calomel electrode.

[2] The thermoelectric conversion layer described in [1], in which the dopant is a compound having a quinoid structure.

[3] The thermoelectric conversion layer described in [1] or [2], in which the dopant is a compound represented by Formula (1) or Formula (2) which will be described later or a compound partially having a structure represented by Formula (1) or Formula (2) which will be described later.

[4] The thermoelectric conversion layer described in any one of [1] to [3], in which a content of the single-layer carbon nanotubes is equal to or greater than 20% by mass with respect to a total mass of the thermoelectric conversion layer.

[5] The thermoelectric conversion layer described in any one of [1] to [4], in which a content of the dopant is 0,01% to 10% by mass with respect to a total mass of the single-layer carbon nanotubes.

[6] The thermoelectric conversion layer described in any one of [1] to [5], further containing a binder.

[7] The thermoelectric conversion layer described in [6], in which at least one kind of the binder is a non-conjugated polymer.

[8] The thermoelectric conversion layer described in [6] or [7], in which a content of the binder is 5% to 100% by mass with respect to the total mass of the single-layer carbon nanotubes.

[9] The thermoelectric conversion layer described in any one of [6] to [8], in which the content of the binder is 20% to 100% by mass with respect to the total mass of the single-layer carbon nanotubes.

[10] The thermoelectric conversion layer described in any one of [1] to [9], in which an index A represented by Equation (1) is 3.5 to 21.

index A=[{T1+(P×10)}×T2/1,000]−(T3×0.01) Equation (1)

In Equation (1), T1 represents a ratio (%) of the semiconducting single-layer carbon nanotubes contained in the single-layer carbon nanotubes, T2 represents a G/D ratio of the single-layer carbon nanotubes, T3 represents a content (% by mass) of the dopant with respect to the single-layer carbon nanotubes, and P represents an oxidation-reduction potential (V) of the dopant with respect to the saturated calomel electrode.

[11] A composition for forming a thermoelectric conversion layer containing single-layer carbon nanotubes and a dopant, in which the single-layer carbon nanotubes contain semiconducting single-layer carbon nanotubes at a ratio equal to or higher than 95% and has a G/D ratio equal to or higher than 40, and the dopant is an organic dopant having a non-onium salt structure and has an oxidation-reduction potential equal to or higher than 0 V with respect to a saturated calomel electrode.

[12] A thermoelectric conversion element comprising the thermoelectric conversion layer described in any one of [1] to [10].

[13] A thermoelectric conversion module comprising a plurality of thermoelectric conversion elements described in [12].

According to the present invention, it is possible to provide a semiconductor layer having excellent thermoelectric conversion performances (particularly, a power factor and a figure of merit Z).

Furthermore, according to the present invention, it is possible to provide a composition for forming a thermoelectric conversion layer used for forming the thermoelectric conversion layer.

In addition, according to the present invention, it is possible to provide a thermoelectric conversion element and a thermoelectric conversion module comprising the thermoelectric conversion layer.

### BRIEF DESCRIPTION OF THE DRAWINGS

FIG. 1 is a cross-sectional view of a first embodiment of a thermoelectric conversion element of the present invention.

FIG. 2 is a cross-sectional view of a second embodiment of the thermoelectric conversion element of the present invention.

FIG. 3A is a conceptual view of a third embodiment of the thermoelectric conversion element of the present invention (top view).

FIG. 3B is a conceptual view of the third embodiment of the thermoelectric conversion element of the present invention (front view).

FIG. 3C is a conceptual view of the third embodiment of the thermoelectric conversion element of the present invention (bottom view).

FIG. 4 is a conceptual view of a fourth embodiment of the thermoelectric conversion element of the present invention.

FIG. 5 is a conceptual view of a fifth embodiment of the thermoelectric conversion element of the present invention.

FIG. 6 is a schematic view of a thermoelectric conversion module prepared in Examples.

FIG. 7 is a schematic view showing a device for measuring output of the thermoelectric conversion module.

### DESCRIPTION OF THE PREFERRED EMBODIMENTS

Hereinafter, the present invention will be specifically described.

The following constituents will be described based on typical embodiments of the present invention in some cases, but the present invention is not limited to the embodiments.

In the present specification, a range of numerical values described using “to” means a range which includes the numerical values listed before and after “to” as a lower limit and an upper limit.

In the present specification, “(meth)acrylate compound” means “either or both of an acrylate compound and a methacrylate compound”.

[Thermoelectric Conversion Layer]

First, the characteristics of the thermoelectric conversion layer according to an embodiment of the present invention will be described.

One of the characteristics of the thermoelectric conversion layer according to the embodiment of the present invention is that the thermoelectric conversion layer contains single-layer carbon nanotubes (hereinafter, referred to as “specific single-layer CNT” as well), which contain semiconducting single-layer carbon nanotubes at a ratio equal to or higher than 95% and has a G/D ratio equal to or higher than 40, and an organic dopant (hereinafter, referred to as “specific dopant” as well) having a non-onium salt structure that has an oxidation-reduction potential equal to or higher than 0 V with respect to a saturated calomel electrode.

Because the thermoelectric conversion layer according to the embodiment of the present invention is constituted as above, the thermoelectric conversion performances (particularly, a power factor and a figure of merit Z) of the thermoelectric conversion layer are markedly better than those of the thermoelectric conversion layers in which the dopants described in JP2016-015361A and Applied Physics Express 9. 025102 (2016) are used. The inventors of the present invention have confirmed that in a case where the specific dopant is used for the specific single-layer CNT, the electric conductivity of the thermoelectric conversion layer is improved while the thermal conductivity thereof is reduced. The inventors consider that as a result, a power factor and a figure of merit Z may become excellent.

As will be described later, in a case where the thermoelectric conversion layer according to the embodiment of the present invention further contains a binder (preferably a non-conjugated polymer and more preferably a hydrogen bonding resin), the thermal conductivity of the thermoelectric conversion layer can be further reduced, and the figure of merit Z is further improved.

Furthermore, compared to the thermoelectric conversion layers in which the dopants described in JP2016-015361A and Applied Physics Express 9. 025102 (2016) are used, the thermoelectric conversion layer according to the embodiment of the present invention results in a smaller variation in thermoelectric conversion performances (particularly, a figure of merit Z) and has excellent temporal stability.

Hereinafter, each of the components contained in the thermoelectric conversion layer according to the embodiment of the present invention will be specifically described.

<Single-Layer Carbon Nanotubes>

The thermoelectric conversion layer according to the embodiment of the present invention contains single-layer CNT.

The single-layer CNT have a structure in which one sheet of carbon film (graphene sheet) is wound in the form of a cylinder. Depending on the winding method, the single-layer CNT are classified into armchair nanotubes, chiral nanotubes, or zigzag nanotubes. The armchair nanotubes are metallic CNT. The metallicity/semiconducting properties of the chiral nanotubes and the zigzag nanotubes are defined by a chiral vector (n, m). That is, CNT in which (n-m) is not a multiple of 3 are referred to as semiconducting CNT and exhibit the characteristics of a semiconductor. In contrast, CNT in which (n-m) is a multiple of 3 are referred to as metallic CNT. Generally, the single-layer CNT are synthesized as a mixture of the semiconducting CNT and the metallic CNT.

The single-layer CNT contained in the thermoelectric conversion layer according to the embodiment of the present invention contain semiconducting single-layer carbon nanotubes at a ratio equal to or higher than 95%. That is, the content of the semiconducting CNT in all the single-layer CNT is equal to or greater than 95%. Hereinafter, the ratio of the semiconducting CNT contained in all the single-layer CNT will be referred to as a semiconductor ratio as well.

In the present specification, the ratio (%) of the semiconducting CNT contained in the single-layer CNT is represented by (number of semiconducting CNT molecules/total number of single-layer CNT molecules)×100.

The ratio (%) of the semiconducting CNT contained in the single-layer CNT is measured by a method such as absorption spectroscopy (for example, Nair et al., Estimation of the (n, m) Concentration Distribution of Single-Walled Carbon Nanotubes from PhotoabsorptionSpectra”, Analytical Chemistry, 2006, Vol. 78, Issue. 22, p 7589-7596.).

Particularly, in view of further improving the thermoelectric conversion performances of the thermoelectric conversion layer, the semiconductor ratio in the single-layer CNT contained in the thermoelectric conversion layer according to the embodiment of the present invention is preferably equal to or higher than 98%.

Examples of methods for obtaining single-layer CNT with a semiconductor ratio equal to or higher than 95% include a method of purifying a single-layer CNT mixture obtained by mixing together semiconducting CNT and metallic CNT by techniques such as density gradient centrifugation and gel filtration column chromatography (separation of semiconducting and metallic CNT), a method of selectively synthesizing semiconducting CNT in the manufacturing process, a method of converting metallic CNT into semiconducting CNT (conversion between semiconducting CNT and metallic CNT), a method of making metallic CNT into an insulating material by reducing electric conductivity thereof (metal invalidation), and the like.

The single-layer CNT can be manufactured by an arc discharge method, a chemical vapor deposition method (hereinafter, referred to as CVD method), a laser ablation method, and the like. The single-layer CNT contained in the thermoelectric conversion layer according to the embodiment of the present invention may be obtained by any method, but it is preferable to obtain the single-layer CNT by the arc discharge method or the CVD method.

At the time of manufacturing the single-layer CNT, fullerene, graphite, and amorphous carbon are also generated as by-products in some cases. In order to remove these by-products, the single-layer CNT may be purified. The single-layer CNT purification method is not particularly limited, and examples thereof include methods such as washing, centrifugation, filtration, oxidation, and chromatography. In addition, an acid treatment using nitric acid, sulfuric acid, or the like and an ultrasonic treatment are also effective for removing impurities. In addition, it is more preferable to separate and remove the by-products by using a filter so as to improve the purity of the semiconducting CNT.

In a case where the single-layer CNT are manufactured and used for manufacturing the thermoelectric conversion layer according to the embodiment of the present invention, after the purification, the obtained single-layer CNT can be used as they are. Generally, the single-layer CNT are generated in the form of strings. Therefore, the single-layer CNT may be cut in a desired length according to the use. By an acid treatment using nitric acid, sulfuric acid, or the like, an ultrasonic treatment, a freezing and pulverizing method, and the like, the single-layer CNT can be cut in the form of shorter fiber.

In a case where the single-layer CNT are used for manufacturing the thermoelectric conversion layer according to the embodiment of the present invention, not only the cut single-layer CNT, but also single-layer CNT prepared in advance in the form of short fiber can also be used.

The average length of the single-layer CNT is not particularly limited. From the viewpoint of ease of manufacturing, film formability, electric conductivity, and the like, the average length of the single-layer CNT is preferably 0.01 to 1,000 μm, and more preferably 0.1 to 100 μm.

The diameter of the single-layer CNT is not particularly limited. From the viewpoint of durability, film formability, electric conductivity, thermoelectric performances, and the like, the diameter of the single-layer CNT is preferably 0.5 to 4.0 nm, more preferably 0.6 to 3.0 nm, and even more preferably 0.7 to 2.0 nm.

(Calculation of Diameter of Single-Layer CNT)

The diameter of the single-layer CNT described in the present specification is evaluated by the following method. That is, a Raman spectrum of the single-layer CNT is measured using excitation light of 532 nm (excitation wavelength: 532 nm), and by a shift ω (RBM) (cm⁻¹) of a radial breathing mode (RBM), the diameter of the single-layer CNT is calculated using the following calculation equation. The value of a maximum peak in the RBM mode is adopted as ω.

Calculation equation: Diameter (nm)=248/ω(RBM)

An intensity ratio G/D (hereinafter, referred to as G/D ratio) between a G-band and a D-hand in a Raman spectrum (excitation wavelength: 532 nm) of the single-layer CNT used in the present invention is equal to or higher than 40.

The G/D ratio is a parameter of the amount of defects of CNT. The higher the G/D ratio, the fewer the defects of CNT, and the better the thermoelectric conversion performances of the thermoelectric conversion layer. Generally, single-layer CNT with a high semiconductor ratio are prepared through a purification (separation of semiconducting CNT and metallic CNT) treatment by techniques such as density gradient centrifugation and gel filtration column chromatography in many cases. The single-layer CNT prepared through the treatment for separation of semiconducting CNT and metallic CNT tend to have many defects and a low G/D ratio. Therefore, it is preferable to perform a treatment for increasing the G/D ratio.

Examples of methods for increasing the G/D ratio include a method of calcining the single-layer CNT in a vacuum. The calcination temperature is not particularly limited, but is 500° C. to 1,200° C. for example. In order to further increase the G/D ratio of the obtained single-layer CNT, the calcination temperature is preferably 800° C. to 1,200° C., and more preferably 900° C. to 1,100° C. The calcination time is not particularly limited, but is 10 to 120 minutes for example. The calcination time is preferably 10 to 60 minutes.

The upper limit of the G/D ratio of the single-layer CNT is not particularly limited, but is about 100 to 200 for example.

In the thermoelectric conversion layer according to the embodiment of the present invention, the content of the specific single-layer CNT is not particularly limited. In the thermoelectric conversion layer, the content of the specific single-layer CNT with respect to the total mass of the thermoelectric conversion layer is preferably equal to or greater than 5% by mass, more preferably equal to or greater than 10% by mass, even more preferably equal to or greater than 20% by mass, particularly preferable 30% by mass, and most preferably equal to or greater than 40% by mass. The upper limit is not particularly limited, but is preferably equal to or smaller than 99.5% by mass for example.

The single-layer CNT may contain a metal or the like or contain a fullerene molecule or the like ((particularly, single-layer CNT containing fullerene are called pivot).

<Dopant>

The thermoelectric conversion layer according to the embodiment of the present invention contains an organic dopant (specific dopant) having a non-onium salt structure that has an oxidation-reduction potential equal to or greater than 0 V with respect to a saturated calomel electrode (hereinafter, simply referred to as “oxidation-reduction potential” as well). Generally, by being oxidized due to the specific dopant, the single-layer CNT become a p-type in many cases.

In the present specification, the organic dopant means a dopant containing at least one carbon atom. The organic dopant having a non-onium salt structure means an organic dopant which does not have an onium salt structure. More specifically, examples thereof include an organic dopant which has none of an ammonium salt structure, a sulfonium salt structure, a phosphonium salt structure, a halonium salt structure, an oxonium salt structure, and a carbonium salt structure.

The onium salt means a salt that a Lewis acid group generates by forming a coordinate bond by using non-bonding electron pairs so as to increase the atomic valence.

in view of further improving the thermoelectric conversion performances of the thermoelectric conversion layer, the oxidation-reduction potential of the specific dopant is preferably equal to or higher than 0.1 V. The upper limit thereof is not particularly limited, but is preferably equal to or lower than 1.5 V and more preferably equal to or lower than 1,0 V,

The oxidation-reduction potential of the specific dopant is measured by cyclic voltammetry by using a saturated calomel electrode as a reference electrode (saturated calomel reference electrode).

Specifically, the oxidation-reduction potential is measured at room temperature (25° C.) by using a dichloromethane solution or an acetonitrile solution containing a 0.1 M electrolyte (as the electrolyte, tetrabutylammonium hexafluorophosphate or tetrabutylammonium perchlorate is used) as an electrolytic solution at a sample concentration of 0.5 mM. Furthermore, as the measurement conditions, a glassy carbon electrode is used as a working electrode, a platinum electrode is used as a counter electrode, and a sweep rate is set to be 5 mV/sec.

The specific dopant is not particularly limited as long as the oxidation-reduction potential thereof is equal to or higher than 0 V. Particularly, in view of excellent temporal stability, it is preferable that the specific dopant has a quinoid structure. That is, the specific dopant is preferably a compound having a quinoid structure. In a case where the specific dopant is a compound having a quinoid structure, due to the quinoid structure, the specific dopant exhibits excellent adsorptivity with respect to the single-layer CNT. It is considered that consequently, the temporal stability of the thermoelectric conversion layer may be excellent. The compound having a quinoid structure may have any of an o-quinoid structure or a p-quinoid structure,

Particularly, in view of further improving the thermoelectric conversion performances, the specific dopant is preferably a compound represented by Formula (1) or Formula (2) or a compound partially having a structure represented by Formula (1) or Formula (2).

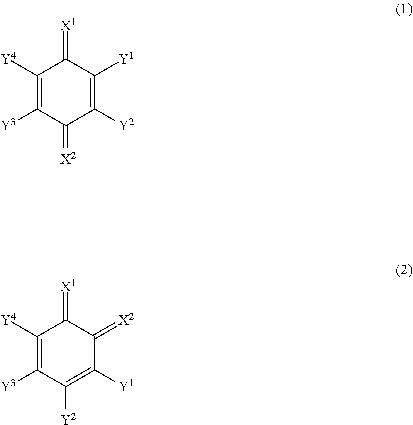

In Formulae (1) and (2), X¹ and X² each independently represent an oxygen atom, a sulfur atom, a group represented by *═C(CN)₂, a group represented by *═C(C(═O)R¹)₂, a group represented by *═C(CN)(C(═O)R¹), a group represented by *═C(CN)(CO₂R¹), a group represented by *═C(CO₂R¹)₂, a group represented by *═C(SO₂R¹)₂, or a group represented by *═C(CN)(SO₂R¹). Among these, in view of further improving the thermoelectric conversion performances of a thermoelectric conversion element, an oxygen atom or a group represented by *═C(CN)₂ is preferable. * represents a binding position.

R¹ represents a monovalent substituent.

The monovalent substituent is not particularly limited, and examples thereof include an aliphatic hydrocarbon group, an aryl group, a polyalkylene oxy group (poly(alkyleneoxy) group), a heterocyclic group, and the like.

Y¹ to Y⁴ each independently represent a hydrogen atom or a monovalent substituent.

The monovalent substituent is not particularly limited as long as the compound represented by Formula (1) or Formula (2) and the compound partially having the structure represented by Formula (1) or Formula (2) have an oxidation-reduction potential equal to or higher than 0 V with respect to a saturated calomel electrode. As the monovalent substituent, a cyano group, a fluorine atom, a chlorine atom, a bromine atom, an iodine atom, a nitro group, an aliphatic hydrocarbon group, an arene sulfonyl group, an alkane sulfonyl group, a heteroarene sulfonyl group, an alkoxy group, an alkylthio group, a polyalkylene oxy group, an aryl group, and a heteroaryl group are preferable.

In Formula (I), Y¹ and Y² may form a ring by being bonded to each other, and Y³ and Y⁴ may form a ring by being bonded to each other. In Formula (2), Y¹ and Y² may form a ring by being bonded to each other, Y² and Y³ may form a ring by being bonded to each other, or Y³ and Y⁴ may form a ring by being bonded to each other.

In a case where the specific dopant is the compound partially having a structure represented by Formula (1) or Formula (2), it is preferable that a monovalent organic group induced at the position of any of Y¹, Y², Y³, or Y⁴ in Formula (1) or Formula (2) is incorporated into the compound. Alternatively, in a case where either or both of X¹ and X² are a group having R′, it is preferable that a monovalent organic group induced at any position of R¹ is incorporated into the compound.

Specifically, examples of the compound partially having a structure represented by Formula (1) or Formula (2) include an oligomer or polymer having a structural unit containing a monovalent organic group induced at the position of any of Y¹, Y², Y³, or Y⁴ in Formula (1) or Formula (2). Furthermore, in a case where either or both of X¹ and X² are a group having R¹, examples of the compound include an oligomer or polymer having a structural unit containing a monovalent organic group induced at any position of R¹.

The molecular weight of the specific dopant is not particularly limited. For example, the molecular weight is preferably equal to or greater than 100, and more preferably equal to or greater than 150. Furthermore, for example, the molecular weight is preferably equal to or smaller than 1,000,000, and more preferably equal to or smaller than 100,000.

In a case where the specific dopant has a molecular weight distribution, the molecular weight of the compound means a weight-average molecular weight. In the present specification, the weight-average molecular weight of the specific dopant is measured by gel permeation chromatography (GPC) and expressed in terms of standard polystyrene.

Specific examples of the organic dopant having a non-onium salt structure that has an oxidation-reduction potential equal to or higher than 0 V will be shown below, but the present invention is not limited thereto. In the following example compounds, “Me” represents a methyl group, and “Et” represents an ethyl group.

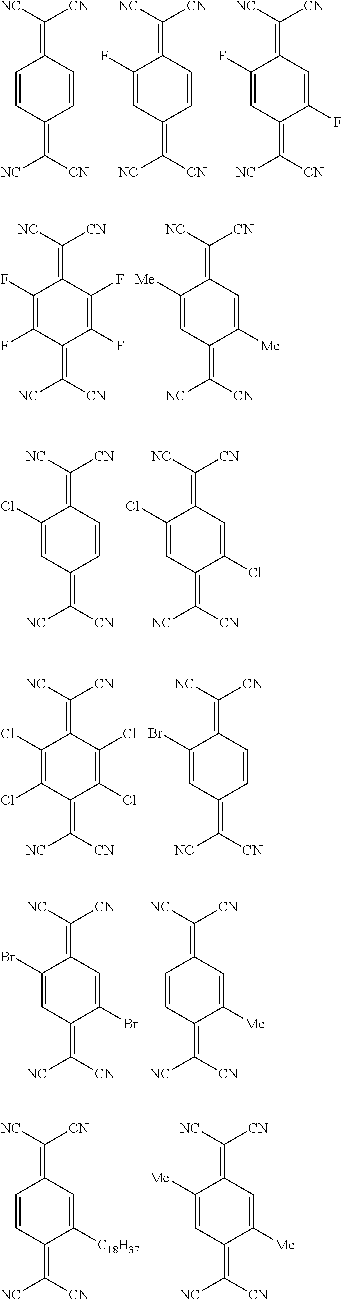

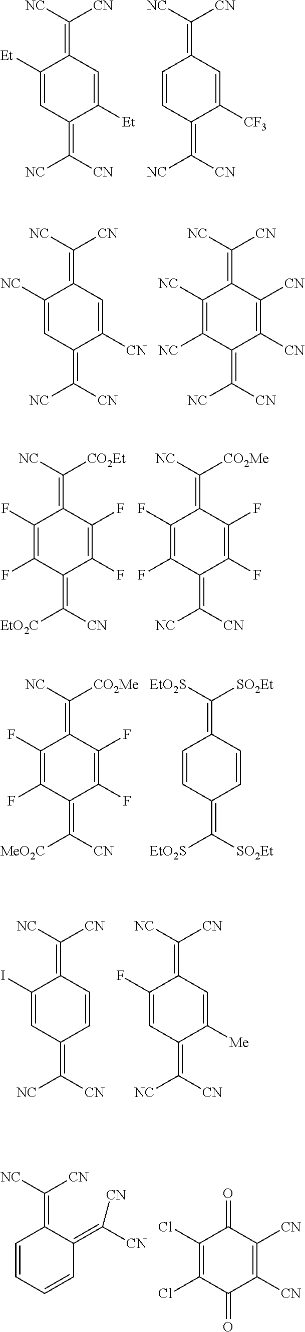

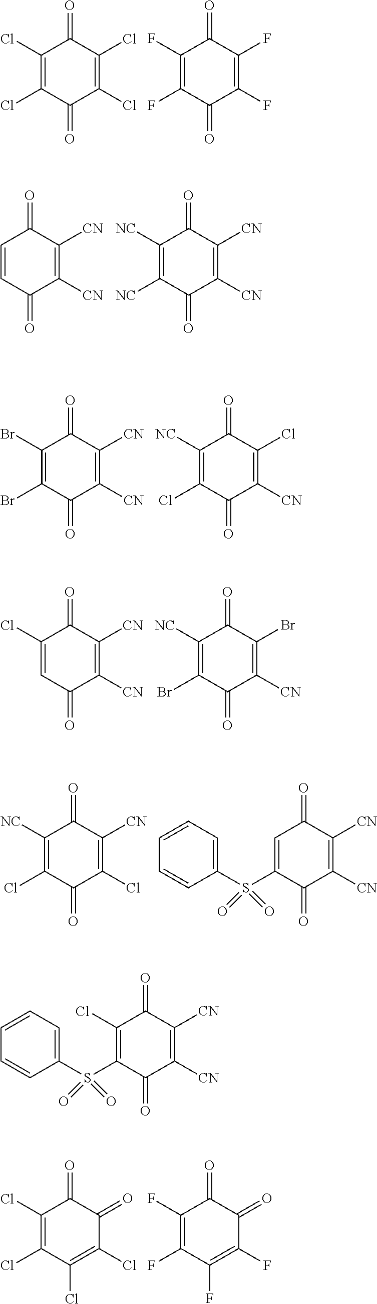

In the thermoelectric conversion layer according to the embodiment of the present invention, the content of the specific dopant is not particularly limited. In the thermoelectric conversion layer, the content of the specific dopant is 0.01% to 35% by mass for example, preferably 0.01% to 10% by mass, and more preferably 0.1% to 5% by mass.

In the thermoelectric conversion layer according to the embodiment of the present invention, the content of the specific dopant with respect to the total mass of the specific single-layer CNT is not particularly limited, but is 0.01% to 50% by mass for example, preferably 0.01% to 10% by mass, more preferably 0.1% to 5% by mass, and even more preferably 0.1% to 4% by mass.

One kind of specific dopant may be used singly, or two or more kinds of the specific dopants may be used in combination.

In the thermoelectric conversion layer according to the embodiment of the present invention, an index A represented by Equation (1) is preferably 3.5 to 21.

The index A is an index showing the relationship between the semiconductor ratio (%) as well as the G/D ratio of the specific single-layer CNT and the oxidation potential (V) as well as the content (% by mass) of the dopant.

The inventors of the present invention have confirmed that in a case where the thermoelectric conversion layer satisfies the index A, the thermoelectric conversion performances thereof are further improved.

The higher the semiconductor ratio (%) and the G/D ratio of the specific single-layer CNT, the more difficult it is to dope the specific single-layer CNT, and hence a highly oxidative dopant needs to be used. Meanwhile, in a case where the content of the dopant in the thermoelectric conversion layer is too large, a Seebeck coefficient is reduced, and consequently, sometimes a figure of merit Z is reduced. In a case where the index A satisfies the range described above, the reduction of the Seebeck coefficient can be inhibited, and hence the reduction of the figure of merit Z can be inhibited.

index A=[{T1+(P×10)}×T2/1,000]−(T3×0.01) Equation (1)

In Equation (1), T1 represents a semiconductor ratio (%) in the specific single-layer CNT, T2 represents a G/D ratio of the specific single-layer CNT, T3 represents a content (% by mass) of the dopant with respect to the single-layer carbon nanotubes, and P represents an oxidation-reduction potential (V) of the dopant with respect to the saturated calomel electrode.

Particularly, the index A is more preferably 3.9 to 21, and even more preferably 3.9 to 11.

<Optional Components>

The thermoelectric conversion layer according to the embodiment of the present invention may contain other components (a binder, a surfactant, an antioxidant, a light-fast stabilizer, a heat-resistance stabilizer, a plasticizer, and the like) in addition to the specific single-layer CNT and the specific dopant. The definition, the specific examples, and the suitable aspect of each of the components are the same as those of each of the components contained in a composition for forming a thermoelectric conversion layer that will be described later.

[Manufacturing Method of Thermoelectric Conversion Layer]

The method for manufacturing a thermoelectric conversion layer is not particularly limited, and examples thereof include a first suitable aspect, a second suitable aspect, and the like described below.

<First Suitable Aspect>

The first suitable aspect of the manufacturing method of a thermoelectric conversion layer is a method of using a composition for forming a thermoelectric conversion layer containing the specific single-layer CNT and the specific dopant.

First, the composition will be described, and then the manufacturing method will be described.

(Composition for Forming Thermoelectric Conversion Layer)

As described above, the composition for forming a thermoelectric conversion layer contains the specific single-layer CNT and the specific dopant.

First, each of the components contained in the composition will be described, and then the preparation method of the composition will be described.

(1) Specific Single-Layer CNT

The definition, the specific examples, and the suitable aspect of the specific single-layer CNT are the same as described above. The content of the specific single-layer CNT in the composition for forming a thermoelectric conversion layer is not particularly limited, but is preferably 0.1% to 20% by mass and more preferably 1% to 10% by mass with respect to the total amount of the composition. The content of the specific single-layer CNT in the solid contents is preferably 5% to 99.5% by mass, more preferably 10% to 90% by mass, and even more preferably 10% to 80% by mass. The solid contents mean components forming a thermoelectric conversion layer, and do not include a solvent.

(2) Specific Dopant

The definition, the specific examples, and the suitable aspect of the specific dopant are the same as described above. The content of the specific dopant in the composition for forming a thermoelectric conversion layer is not particularly limited, but is preferably 0.05% to 20% by mass and more preferably 0.1% to 10% by mass with respect to the total amount of the composition. The content of the specific dopant in the solid contents is more preferably equal to or greater than 0.1% by mass, even more preferably equal to or greater than 1% by mass, and particularly preferably equal to or greater than 5% by mass. Furthermore, the content of the specific dopant in the solid contents is preferably equal to or smaller than 60% by mass, more preferably equal to or smaller than 50% by mass, and even more preferably equal to or smaller than 40% by mass. The solid contents mean components forming a thermoelectric conversion layer, and do not include a solvent.

(3) Dispersion Medium

It is preferable that the composition for forming a thermoelectric conversion layer contains a dispersion medium in addition to the specific single-layer CNT and the specific dopant.

The dispersion medium (solvent) is not limited as long as it can disperse the specific single-layer CNT, and water, an organic solvent, and a mixed solvent of these can be used. Examples of the organic solvent include an alcohol-based solvent, an aliphatic halogen-based solvent such as chloroform, an aprotic polar solvent such as dimethylformamide (DMF), N-methylpyrrolidone (NMP), or dimethylsulfoxide (DMSO), an aromatic solvent such as chlorobenzene, dichlorobenzene, benzene, toluene, xylene, mesitylene, tetralin, tetramethylbenzene, or pyridine, a ketone-based solvent such as cyclohexanone, acetone, or methyl ethyl ketone, an ether-based solvent such as diethyl ether, tetrahydrofuran (THF), t-butyl methyl ether, dimethoxyethane, or diglyme, and the like.

One kind of dispersion medium can be used singly, or two or more kinds of dispersion media can be used in combination.

It is preferable that the dispersion medium is deaerated in advance. The dissolved oxygen concentration in the dispersion medium is preferably equal to or lower than 10 ppm. Examples of deaeration methods include a method of irradiating the dispersion medium with ultrasonic waves under reduced pressure, a method of performing bubbling of an inert gas such as argon, and the like.

In a case where a medium other than water is used as the dispersion medium, it is preferable that the medium is dehydrated in advance. The amount of moisture in the dispersion medium is preferably equal to or smaller than 1,000 ppm, and more preferably equal to or smaller than 100 ppm. As the method for dehydrating the dispersion medium, it is possible to use known methods such as a method of using a molecular sieve and distillation.

The content of the dispersion medium in the composition for forming a thermoelectric conversion is preferably 25% to 99.85% by mass with respect to the total amount of the composition.

(4) Other Components

The composition for forming a thermoelectric conversion layer may contain a binder, a surfactant, an antioxidant, a light-fast stabilizer, a heat-resistance stabilizer, a plasticizer, and the like in addition to the components described above.

Examples of the binder include a conjugated polymer and a non-conjugated polymer. The binder brings about an effect of reducing the thermal conductivity by adjusting the distance between CNT.

Examples of the conjugated polymer include polythiophene, polyolefin, polyethylenedioxythiophene/polystyrene sulfonate (PEDOT-PSS), polyaniline, polypyrrole, and the like. Examples of the non-conjugated polymer include polystyrene, poly(meth)acrylate, polycarbonate, polyester, an epoxy compound, polysiloxane, gelatin, and the like.

Particularly, in view of further improving the thermoelectric conversion performances (particularly, a figure of merit Z) of the thermoelectric conversion layer, the binder is preferably a non-conjugated polymer, and more preferably a resin (hydrogen bonding resin) having a hydrogen bonding functional group.

The hydrogen bonding functional group may be a functional group having hydrogen bonding properties. Examples thereof include a OH group, a NH₂ group, a NHR group (R represents an aromatic group or an aliphatic hydrocarbon group), a COOH group, a CONH₂ group, a NHOH group, a SO₃H group (sulfonic acid group), a —OP(═O)OH₂ group (phosphoric acid group), a group having a —NHCO— group, a —NH— group, a —CONHCO— bond, a —NH—NH— bond, a —C(═O)— group (carbonyl group), or a —ROR— group (ether group: R each independently represents a divalent aromatic hydrocarbon group or a divalent aliphatic hydrocarbon group; here, two R's may be the same as or different from each other), and the like.

Examples of the hydrogen bonding resin include carboxymethyl cellulose, carboxyethyl cellulose, methyl cellulose, ethyl cellulose, hydroxymethyl cellulose, hydroxyethyl cellulose, methyl hydroxypropyl cellulose, hydroxypropyl methyl cellulose, crystalline cellulose, xanthan gum, guar gum, hydroxyethyl guar gum, carboxymethyl guar gum, gum tragacanth, locust bean gum, tamarind seed gum, psyllium seed gum, quince seeds, carrageenan, galactan, gum. Arabic, pectin, pullulan, mannan, glucomannan, starch, curdlan, chondroitin sulfate, dermatan sulfate, glycogen, heparan sulfate, hyaluronic acid, keratan sulfate, chondroitin, mucoitin sulfate, dextran, keratosulfate, succinoglucan, karonin acid, alginic acid, propylene glycol alginate, macrogol, chitin, chitosan, carboxymethyl chitin, gelatin, agar, polyvinyl alcohol, polyvinyl pyrrolidone, a carboxyvinyl polymer, an alkyl-modified carboxyvinyl polymer, polyacrylic acid, an acrylic acid/alkyl methacrylate copolymer, polyethylene glycol, a (hydroxyethyl acrylate/sodium acryloyldimethyltaurate) copolymer, an (ammonium acryloyldimethyltaurate/vinyl pyrrolidone) copolymer, chemically modified starch, bentonite, and the like. In a case where the hydrogen bonding resin has an acidic group such as a carboxy group, the hydrogen bonding resin may partially or totally become a salt such as a sodium salt, a potassium salt, or an ammonium salt.

The weight-average molecular weight of the conjugated polymer or the non-conjugated polymer described above is not particularly limited, but is equal to or greater than 1,000 for example, preferably equal to or greater than 5,000, and more preferably 7,000 to 300,000. The weight-average molecular weight is measured by Gel Permeation Chromatography (GPC) and expressed in terms of standard polystyrene.

The content of the binder with respect to the total mass of the specific single-layer CNT is preferably 5% to 100% by mass, and more preferably 20% to 100% by mass, because then the thermal conductivity is further reduced, and the electric conductivity is not hindered.

Examples of the surfactant include known surfactants (a cationic surfactant, an anionic surfactant, a nonionic surfactant, and the like). Among these, an anionic surfactant is preferable, and sodium deoxycholate, sodium cholate, or sodium dodecylbenzene sulfonate is more preferable. The surfactant functions as a dispersant.

The content of the surfactant with respect to the total amount of the composition is preferably 0.1% to 20% by mass, and more preferably 1% to 10% by mass.

The thermoelectric conversion layer may further contain an antioxidant, a light-fast stabilizer, a heat-resistance stabilizer, a plasticizer, and the like.

Examples of the antioxidant include IRGANOX 1010 (manufactured by Ciba-Geigy Japan Limited), SUMILIZER GA-80 (manufactured by Sumitomo Chemical Co., Ltd.), SUMILIZER GS (manufactured by Sumitomo Chemical Co., Ltd), SUMILIZER GM (manufactured by Sumitomo Chemical Co., Ltd.), and the like.

Examples of the light-fast stabilizer include TINUVIN 234 (manufactured by BASF SE), CHIMASSORB 81 (manufactured by BASF SE), CYASORB UV-3853 (manufactured by SUN CHEMICAL COMPANY LTD.), and the like.

Examples of the heat-resistance stabilizer include IRGANOX 1726 (manufactured by BASF SE).

Examples of the plasticizer include ADK CIZER RS (manufactured by ADEKA CORPORATION) and the like.

(Preparation Method of Composition for Forming Thermoelectric Conversion Layer)

The composition for forming a thermoelectric conversion layer can be prepared by mixing together the components described above. The composition is preferably prepared by mixing together the dispersion medium, the specific single-layer CNT, the specific dopant, and other components which are used if desired, and dispersing the specific single-layer CNT.

The preparation method of the composition is not particularly limited, and can be performed using a general mixing device or the like at room temperature under normal pressure. For example, the composition may be prepared by dissolving or dispersing the components in a solvent by means of stirring, shaking, or kneading. In order to accelerate the dissolution and dispersion, an ultrasonic treatment may be perfoiiiied.

Furthermore, it is possible to improve the dispersibility of the single-layer CNT by means of heating the solvent to a temperature that is equal to or higher than room temperature and equal to or lower than the boiling point in the aforementioned dispersion step, extending the dispersion time, increasing the intensity of stirring, shaking, kneading, or ultrasonic waves applied, and the like.

The amount of the specific dopant to be used is not particularly limited. In the composition, the content of the specific dopant with respect to the content of the specific single-layer CNT is preferably 0.1% to 200% by mass, and more preferably 5% to 100% by mass.

(Manufacturing Method)

The method for manufacturing a thermoelectric conversion layer by using the composition for forming a thermoelectric conversion layer is not particularly limited, and examples thereof include a method for forming a film by coating a substrate with the aforementioned composition.

The film-forming method is not particularly limited, and it is possible to use known coating methods such as a spin coating method, an extrusion die coating method, a blade coating method, a bar coating method, a screen printing method, a stencil printing method, a metal mask printing method, a roll coating method, a curtain coating method, a spray coating method, a dip coating method, and an ink jet method.

If necessary, a drying step is performed after coating. For example, by blowing hot air to the thermoelectric conversion layer, the solvent can be volatilized and dried.

In a case where the composition for forming a thermoelectric conversion layer contains a dispersant (for example, a surfactant such as sodium deoxycholate), it is preferable to immerse the coating film obtained by the drying described above in water or an organic solvent, in which CNT are not dissolved but the aforementioned dispersant can be dissolved, so as to remove the dispersant from the coating film. In a case where the dispersant is a surfactant such as sodium deoxycholate, as an organic solvent, it is possible to use methanol, ethanol, propanol, isopropanol, ethylene glycol, propylene glycol, acetone, 2-butanone, propylene glycol 1-monomethyl ether 2-acetate, 1-methoxy-2-propanol, dimethyl sulfoxide, butanol, sec-butanol, isobutyl alcohol, tert-butanol, glycerin, acetonitrile, N,N-dimethylformamide, N,N-dimethylacetamide, tetrahydrofuran, 1,4-dioxane, 1,3-dimethyl-2-imidazolidinone, N-methylpyrrolidone, N-ethylpyrrolidone, methyl carbitol, butyl carbitol, methyl acetate, ethyl acetate, cyclohexanone, and the like. The immersion time is no particularly limited, but is 5 minutes to 24 hours for example.

<Second Suitable Aspect>

The second suitable aspect of the manufacturing method of a thermoelectric conversion layer is a method of preparing a thermoelectric conversion layer precursor by using a composition for forming a thermoelectric conversion layer precursor containing the specific single-layer CNT and then doping the thermoelectric conversion layer precursor with the specific dopant described above.

First, the composition will be described, and then the manufacturing method will be described.

(Composition for Forming Thermoelectric Conversion Layer Precursor)

As described above, the composition for forming a thermoelectric conversion layer precursor contains the specific single-layer CNT. The definition, the specific examples, and the suitable aspect of the specific single-layer CNT are as described above. The suitable aspect of the content of the specific single-layer CNT in the composition is the same as that in the first suitable aspect described above.

It is preferable that the composition for forming a thermoelectric conversion layer precursor contains a dispersion medium in addition to the specific single-layer CNT. Specific examples and suitable aspects of the dispersion medium are the same as those in the first suitable aspect described above.

The composition for forming a thermoelectric conversion layer precursor may further contain other components. Specific examples and suitable aspects of those other components are the same as those in the first suitable aspect described above.

(Manufacturing Method)

The method for manufacturing a thermoelectric conversion layer precursor by using the composition for forming a thermoelectric conversion layer precursor is not particularly limited, and specific examples and suitable aspects of the method are the same as those in the manufacturing method of a thermoelectric conversion layer of the first suitable aspect described above. Furthermore, the thermoelectric conversion layer precursor may be processed, for example, in the form of buckypaper or a sheet by using a dispersion liquid obtained by dispersing single-layer CNT in a polymer compound used as a binder.

In the second suitable aspect, after a thermoelectric conversion layer precursor is prepared, the precursor is doped with the specific dopant described above. In this way, a thermoelectric conversion layer is obtained.

The doping method is not particularly limited as long as the specific dopant is used. Examples thereof include a method of immersing the thermoelectric conversion layer precursor in a solution obtained by dissolving the specific dopant in a solvent, and the like. Specific examples of the solvent are the same as the examples of the dispersion medium described above.

The amount of the specific dopant used in the second suitable aspect is not particularly limited. The content of the specific dopant used for doping with respect to the content of the specific single-layer CNT in the thermoelectric conversion layer precursor is preferably 0.01% to 20,000% by mass, and more preferably 0.1% to 2,000% by mass.

After the doping, if necessary, a drying step is performed. For example, by blowing hot air to the thermoelectric conversion layer, the solvent can be volatilized and dried.

[Thickness]

From the viewpoint of causing a temperature difference and the like, the average thickness of the thermoelectric conversion layer according to the embodiment of the present invention is preferably 1 to 500 μm, more preferably 2 to 300 μm, even more preferably 3 to 200 μm, and particularly preferably 5 to 100 μm.

The average thickness of the thermoelectric conversion layer is determined by measuring the thickness of the thermoelectric conversion layer at 10 random points and calculating the arithmetic mean thereof.

[Thermoelectric Conversion Element and Thermoelectric Conversion Module]

The constitution of the thermoelectric conversion element according to the embodiment of the present invention is not particularly limited as long as the thermoelectric conversion element comprises the aforementioned thermoelectric conversion layer. For example, in an aspect, the thermoelectric conversion element according to the embodiment of the present invention comprises the aforementioned thermoelectric conversion layer and an electrode pair which is electrically connected to the thermoelectric conversion layer. It is preferable that the thermoelectric conversion element according to the embodiment of the present invention comprises the aforementioned thermoelectric conversion layer as a p-type thermoelectric conversion layer.

The constitution of the thermoelectric conversion module according to the embodiment of the present invention is not particularly limited as long as the thermoelectric conversion module comprises a plurality of thermoelectric conversion elements described above.

Hereinafter, for each of the thermoelectric conversion element comprising the thermoelectric conversion layer according to the embodiment of the present invention and the thermoelectric conversion module comprising a plurality of thermoelectric conversion elements described above, a suitable aspect will he specifically described.

In the thermoelectric conversion element according to the embodiment of the present invention, the thermoelectric conversion layer may include only the thermoelectric conversion layer according to the embodiment of the present invention or further comprise, for example, a p-type thermoelectric conversion layer by causing the thermoelectric conversion layer according to the embodiment of the present invention to function as a p-type thermoelectric conversion layer and an n-type thermoelectric conversion layer electrically connected to the p-type thermoelectric conversion layer. As long as the n-type thermoelectric conversion layer and the p-type thermoelectric conversion layer are electrically connected to each other, these layers may directly contact each other, or a conductor (for example, an electrode) may be disposed between the layers.

### First Embodiment

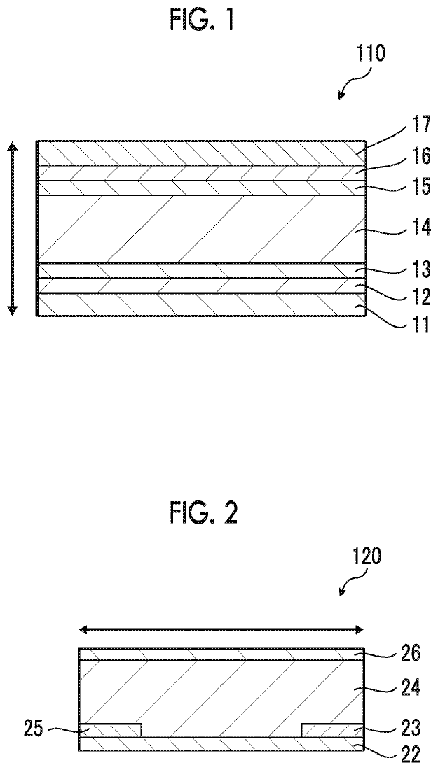

FIG. 1 is a cross-sectional view of a first embodiment of the thermoelectric conversion element of the present invention.

A thermoelectric conversion element 110 shown in FIG. 1 comprises a first substrate 12, a pair of electrodes including a first electrode 13 and a second electrode 15 on the first substrate 12, and a thermoelectric conversion layer 14 which is between the first electrode 13 and the second electrode 15 and contains the specific single-layer CNT and the specific dopant. On the other surface of the second electrode 15, a second substrate 16 is disposed. On the outside of the first substrate 12 and the second substrate 16, metal plates 11 and 17 facing each other are disposed.

### Second Embodiment

FIG. 2 is a cross-sectional view of a second embodiment of the thermoelectric conversion element of the present invention.

A thermoelectric conversion element 120 shown in FIG. 2 is provided with a first substrate 22, a first electrode 23 and a second electrode 25 on the first substrate 22, and a thermoelectric conversion layer 24 which is on the electrodes and contains the specific single-layer CNT and the specific dopant. The other surface of the thermoelectric conversion layer 24 is provided with a second substrate 26.

### Third Embodiment

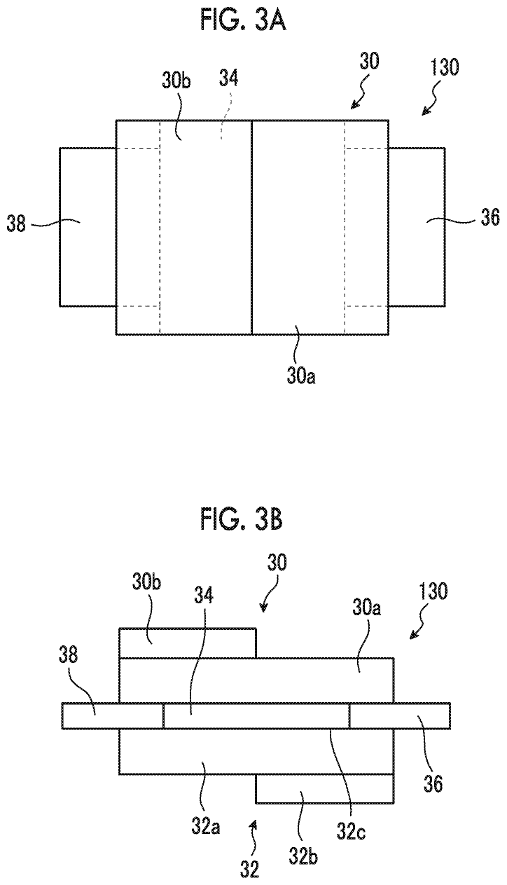

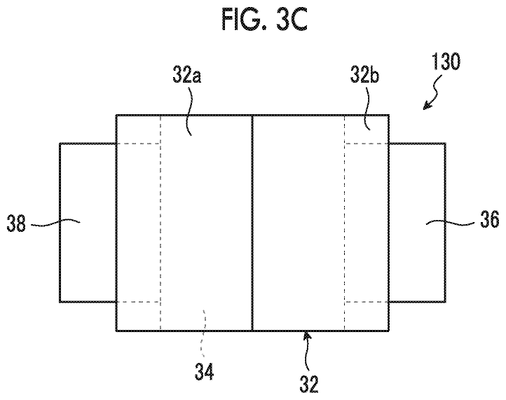

FIGS. 3A to 3C conceptually show a third embodiment of the thermoelectric conversion element of the present invention. FIG. 3A is a top view (a drawing obtained in a case where FIG. 3B is viewed from above the paper), FIG. 3B is a front view (a drawing obtained in a case where the thermoelectric conversion element is viewed from the plane direction of a substrate, which will be described later, and the like), and FIG. 3C is a bottom view (a drawing obtained in a case where FIG. 3B is viewed from the bottom of the paper).

As shown in FIGS. 3A to 3C, a thermoelectric conversion element 130 is basically constituted with a first substrate 32, a thermoelectric conversion layer 34 containing the specific single-layer CNT and the specific dopant, a second substrate 30, a first electrode 36, and a second electrode 38.

Specifically, on a surface of the first substrate 32, the thermoelectric conversion layer 34 is formed. Furthermore, on the surface of the first substrate 32, the first electrode 36 and the second electrode 38 (electrode pair) are formed which contact the thermoelectric conversion layer 34 interposed between the electrodes in a substrate surface direction of the first substrate 32 (hereinafter, the substrate surface direction will be simply referred to as “plane direction” as well which is in other words a direction orthogonal to the direction along which the first substrate 32 and the second substrate 30 are laminated).

A pressure sensitive adhesive layer may be disposed between the first substrate 32 and the thermoelectric conversion layer 34 or between the second substrate 30 and the thermoelectric conversion layer 34, although the pressure sensitive adhesive layer is not shown in FIGS. 3A to 3C.

As shown in FIGS. 3A to 3C, the first substrate 32 includes a low thermal conduction portion 32a and a high thermal conduction portion 32b having a thermal conductivity higher than that of the low thermal conduction portion 32a. Likewise, the second substrate 30 includes a low thermal conduction portion 30a and a high thermal conduction portion 30b having a thermal conductivity higher than that of the low thermal conduction portion 30a.

In the thermoelectric conversion element 130, the two substrates are disposed such that the high thermal conduction portions thereof are in different positions in a direction along which the first electrode 36 and the second electrode 38 are spaced apart from each other (that is, a direction along which electricity is conducted).

In a preferable aspect, the thermoelectric conversion element 130 has the second substrate 30 bonded through a pressure sensitive adhesive layer, and both the first substrate 32 and the second substrate 30 have a low thermal conduction portion and a high thermal conduction portion. The thermoelectric conversion element 130 has a constitution in which two sheets of substrates each having a high thermal conduction portion and a low thermal conduction portion are used such that the thermoelectric conversion layer is interposed between the two sheets of substrates in a state where the high thermal conduction portions of the two substrates are in different positions in the plane direction.

That is, the thermoelectric conversion element 130 is a thermoelectric conversion element which converts thermal energy into electric energy by causing a temperature difference in the plane direction of the thermoelectric conversion layer (hereinafter, the thermoelectric conversion element will be referred to as in plane-type thermoelectric conversion element as well). In the example illustrated in the drawing, by using a substrate including a low thermal conduction portion and a high thermal conduction portion having a thermal conductivity higher than that of the low thermal conduction portion, a temperature difference can be caused in the plane direction of the thermoelectric conversion layer 34, and thermal energy can be converted into electric energy.

### Fourth Embodiment

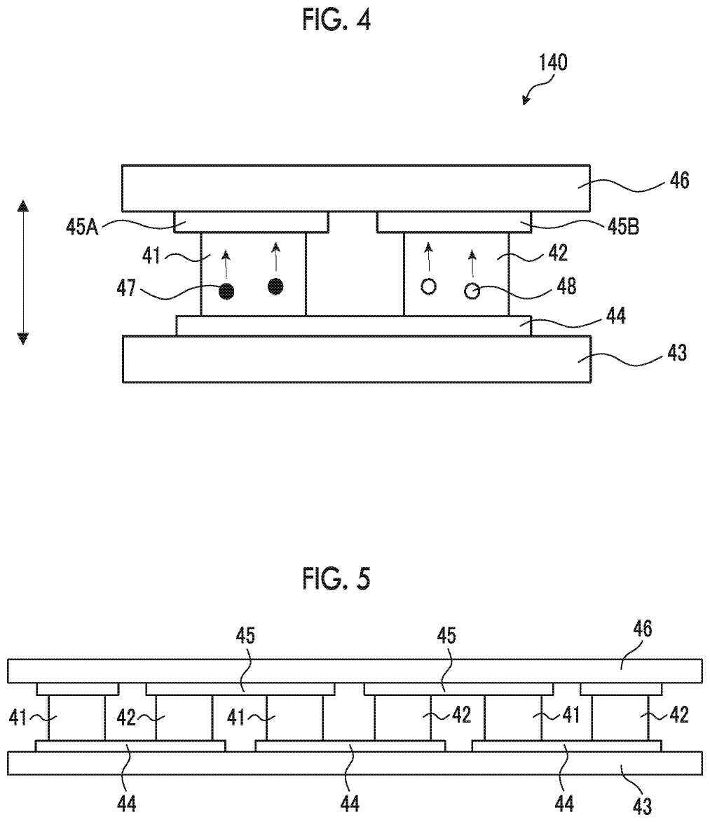

FIG. 4 conceptually shows a fourth embodiment of the thermoelectric conversion element. In the following embodiment, a case where the thermoelectric conversion layer is used as a p-type thermoelectric conversion layer will be specifically described.

A thermoelectric conversion element 140 shown in FIG. 4 has an n-type thermoelectric conversion layer (n-type thermoelectric conversion portion) 41 and a p-type thermoelectric conversion layer (p-type thermoelectric conversion portion) 42, and these layers are disposed in parallel to each other. The p-type thermoelectric conversion layer 42 is a p-type thermoelectric conversion layer containing the specific single-layer CNT and the specific dopant. The constitution of the n-type thermoelectric conversion layer 41 will be specifically described later.

An upper end portion of the n-type thermoelectric conversion layer 41 is electrically and mechanically connected to a first electrode 45A, and an upper end portion of the p-type thermoelectric conversion layer 42 is electrically and mechanically connected to a third electrode 45B. On the outside of the first electrode 45A and the third electrode 45B, an upper substrate 46 is disposed. A lower end portion of each of the n-type thermoelectric conversion layer 41 and the p-type thermoelectric conversion layer 42 is electrically and mechanically connected to a second electrode 44 supported on a lower substrate 43. In this way, the n-type thermoelectric conversion layer 41 and the p-type thermoelectric conversion layer 42 are connected to each other in series through the first electrode 45A, the second electrode 44, and the third electrode 45B. That is, the n-type thermoelectric conversion layer 41 and the p-type thermoelectric conversion layer 42 are electrically connected to each other through the second electrode 44.

The thermoelectric conversion element 140 makes a temperature difference (in the direction of the arrow in FIG. 4) between the upper substrate 46 and the lower substrate 43 such that, for example, the upper substrate 46 side becomes a low-temperature portion and the lower substrate 43 side becomes a high-temperature portion. In a case where such a temperature difference is made, in the interior of the n-type thermoelectric conversion layer 41, an electron 47 carrying a negative charge moves to the low-temperature portion side (upper substrate 46 side), and the potential of the second electrode 44 becomes higher than that of the first electrode 45A. In contrast, in the interior of the p-type thermoelectric conversion layer 42, a hole 48 carrying a positive charge moves to the low-temperature portion side (upper substrate 46 side), and the potential of the third electrode 45 B becomes higher than that of the second electrode 44. Consequently, a potential difference occurs between the first electrode 45A and the third electrode 45B, and for example, in a case where a load is connected to the end of the electrode, electric power can be extracted. At this time, the first electrode 45A becomes a negative electrode, and the third electrode 45B becomes a positive electrode.

### Fifth Embodiment

The thermoelectric conversion element 140 can obtain a higher voltage by, for example, alternately disposing a plurality of n-type thermoelectric conversion layers 41, 41 . . . and a plurality of p-type thermoelectric conversion layers 42, 42, and connecting them to each other in series through the first and third electrodes 45 and the second electrode 44, as shown in FIG. 5.

As shown in FIG. 5, in the present invention, a plurality of thermoelectric conversion elements may be electrically connected to each other so as to constitute a so-called module (thermoelectric conversion module).

Hereinafter, each of the members constituting the thermoelectric conversion element will be specifically described.

<Substrate>

As the substrates in the thermoelectric conversion element (the first substrate 12 and the second substrate 16 in the first embodiment, the first substrate 22 and the second substrate 26 in the second embodiment, the low thermal conduction portions 32a and 30a in the third embodiment, and the upper substrate 46 and the lower substrate 43 in the fourth embodiment), substrates such as glass, transparent ceramics, and a plastic film can be used. In the thermoelectric conversion element according to the embodiment of the present invention, it is preferable that the substrate has flexibility. Specifically, it is preferable that the substrate has such flexibility that the substrate is found to have an MIT folding endurance equal to or greater than 10,000 cycles by a measurement method specified by ASTM D2176. As the substrate has such flexibility, a plastic film is preferable, and specific examples thereof include a polyester film such as polyethylene terephthalate, polyethylene isophthalate, polyethylene naphthalate, polybutylene terephthalate, poly(1,4-cyclohexylenedimethyleneterephthalate), polyethylene-2,6-naphthalenedicarboxylate, or a polyester film of bisphenol A and isophthalic and terephthalic acids, a polycycloolefin film such as a ZEONOR film (trade name, manufactured by ZEON CORPORATION), an ARTON film (trade name, manufactured by JSR Corporation), or SUMILITE FS1700 (trade name, manufactured by Sumitomo Bakelite Co. Ltd.), a polyimide film such as KAPTON (trade name, manufactured by DU PONT-TORAY CO., LTD.), APICAL (trade name, manufactured by Kaneka Corporation), UPILEX (trade name, manufactured by UBE INDUSTRIES, LTD.), or POMIRAN (trade name, manufactured by Arakawa Chemical Industries, Ltd.), a polycarbonate film such as PUREACE (trade name, manufactured by TEIJIN LIMITED) or ELMEC (trade name, manufactured by Kaneka Corporation), a polyether ether ketone film such as SUMILITE FS1100 (trade name, manufactured by Sumitomo Bakelite Co. Ltd.); a polyphenyl sulfide film such as TORELINA (trade name, manufactured by TORAY INDUSTRIES, INC.); and the like. From the viewpoint of ease of availability, heat resistance (preferably equal to or higher than 100° C.), and economic feasibility, commercial polyethylene terephthalate, polyethylene naphthalate, various polyimide or polycarbonate films, and the like are preferable.

From the viewpoint of handleability, durability, and the like, the thickness of the substrate is preferably 5 to 3,000 μm, more preferably 5 to 500 μm, even more preferably 5 to 100 μm, and particularly preferably 5 to 50 μm. In a case where the thickness of the substrate is within the above range, a temperature difference can be effectively caused in the thermoelectric conversion layer, and the thermoelectric conversion layer is not easily damaged due to an external shock.

<Electrode>

Examples of electrode materials forming the electrodes in the thermoelectric conversion element include a transparent electrode material such as Indium-Tin-Oxide (ITO) or ZnO, a metal electrode material such as silver, copper, gold, or aluminum; a carbon material such as CNT or graphene; and an organic material such as poly(3,4-ethylenedioxythiophene) (PEDOT)/polystyrene sulfonate (PSS), or PEDOThosylate (Tos). The electrodes can be formed using a conductive paste in which conductive fine particles of gold, silver, copper, or carbon are dispersed, solder, a conductive paste containing metal nanowires of gold, silver, copper, or aluminum, and the like.

<n-Type Thermoelectric Conversion Layer>

As the n-type thermoelectric conversion layer included in the thermoelectric conversion element of the fourth embodiment and the thermoelectric conversion module of the fifth embodiment, a known n-type thermoelectric conversion layer can be used. As materials contained in the n-type thermoelectric conversion layer, known materials are appropriately used.

The n-type thermoelectric conversion layer can be formed (manufactured) by the same method as the manufacturing method of the thermoelectric conversion layer according to the embodiment of the present invention described above.

[Article for Thermoelectric Power Generation]

The thermoelectric conversion element according to the embodiment of the present invention can be used in various articles for thermoelectric power generation. Specific examples of the articles for thermoelectric power generation include a power generator such as a hot spring heat power generator, a solar power generator, or a waste heat power generator, and a power supply such as a power supply for a wristwatch, a power supply for driving a semiconductor, or a power supply for a small sensor. In addition, the articles for thermoelectric power generation in which the thermoelectric conversion layer according to the embodiment of the present invention is used can also be used as a Peltier element for cooling, temperature control, and the like.

### EXAMPLES

Hereinafter, the present invention will be more specifically described based on examples. The materials, the amount and the ratio of the materials used, the details of a treatment, the procedure of a treatment, and the like shown in the following examples can be appropriately changed as long as the gist of the present invention is maintained. Therefore, the scope of the present invention is not limited to the following examples.

1. Preparation of thermoelectric conversion layers of Examples 1 to 21 and Comparative Examples 1 to 11

### Example 1

Single-layer CNT (manufactured by Nanointegris, 20 mg) with a semiconductor ratio of 95% were calcined for 30 minutes at 1,000° C. in a vacuum. By using a homogenizer with a blade (manufactured by SMT Corporation, HIGH-FLEX HOMOGENIZER HF93), a mixture of the calcined single-layer CNT and 20 mL of acetone was dispersed for 5 minutes. The obtained dispersion was collected by filtration and then formed into a film, thereby obtaining buckypaper. By using a hot plate, the buckypaper was dried for 1 hour at 120° C. and then cut in a size of 1 cm×1 cm.

The obtained 1 cm×1 cm sample was immersed for 1 hour in a 2-butanone solution containing 10 mM tetracyanoquinodimethane (TCNQ, manufactured by TOKYO CHEMICAL INDUSTRY CO., LTD.) at room temperature. After 2 hours of immersion, the sample was pulled up and dried for 2 hours at 30° C. In a vacuum. The film obtained after drying was pressed under 30 kN by using a roll press machine, thereby obtaining a thermoelectric conversion layer which was adopted as a sample for measurement.

### Example 2

A mixture of 200 mg of single-layer CNT (manufactured by Nanointegris) with a semiconductor ratio of 95% that were calcined under the same conditions as in Example 1, 600 mg of sodium deoxycholate (manufactured by TOKYO CHEMICAL INDUSTRY CO., LTD.), and 16 mL of water was mixed for 7 minutes by using a mechanical homogenizer (manufactured by SMT Corporation, HIGH-FLEX HOMOGENIZER HF93), thereby obtaining a premix. A mixture of the obtained premix and 100 mg of TCNQ was subjected to a dispersion treatment for 7 minutes in a constant-temperature tank with a temperature equal to or lower than 10° C. by using a thin film revolution-type high-speed mixer “FILMIX 40-40 model” (manufactured by PRIMIX Corporation). By using a rotation·revolution mixer (manufactured by THINK.Y CORPORATION, AWATORI RENTARO ARE-310), the obtained dispersion composition was defoamed, thereby preparing a CNT dispersion liquid.

Three sheets of frames (thickness: 0.2 mm) made of TEFLON (registered trademark) were stuck to a glass substrate having a thickness of 1.1 mm and a size of 40 mm×50 mm, and the area in the frames was coated with the obtained CNT dispersion liquid. Then, the CNT dispersion liquid used for coating was dried for 30 minutes at 50° C. and then for 30 minutes at 120° C., thereby obtaining a printing film. The obtained printing film was immersed in ethanol for 1 hour so as to remove the dispersant, and then peeled from the glass substrate, thereby obtaining a self-supported film. The self-supported film was dried for 30 minutes at 50° C. and then for 150 minutes at 120° C. The obtained film was pressed under 30 kN by using a roll press machine (manufactured by TESTER SANGYO CO., LTD.), thereby obtaining a thermoelectric conversion layer. The thermoelectric conversion layer was cut in a size of 1 cm×1 cm, thereby obtaining a sample for measurement.

### Examples 3 to 9, 16 to 18, 20, and 21

Samples for measurement of Examples 3 to 9, 16 to 18, 20, and 21 were prepared by the same method as that in Example 2 under the conditions described in Table 1.

### Example 10

A mixture of 200 mg of single-layer CNT (manufactured by Nanointegris) with a semiconductor ratio of 98% that were calcined under the same conditions as in Example 1, 600 mg of sodium deoxycholate (manufactured by TOKYO CHEMICAL INDUSTRY CO., LTD.), 100 mg of sodium carboxymethyl cellulose (corresponding to “CMC-Na” in the table), and 16 mL of water was mixed for 7 minutes by using a mechanical homogenizer (manufactured by SMT Corporation, HIGH-FLEX HOMOGENIZER HF93), thereby obtaining a premix. A mixture of the obtained premix and 100 mg of TCNQ was subjected to a dispersion treatment for 7 minutes in a constant-temperature tank with a temperature equal to or lower than 10° C. by using a thin film revolution-type high-speed mixer “FILMIX 40-40 model” (manufactured by PRIMIX Corporation). By using a rotation·revolution mixer (manufactured by THINKY CORPORATION, AWATORI RENTARO ARE: 310), the obtained dispersion composition was defoamed, thereby preparing a CNT dispersion liquid.

Three sheets of frames (thickness: 0.2 mm) made of TEFLON (registered trademark) were stuck to a glass substrate having a thickness of 1.1 mm and a size of 40 mm×50 mm, and the area in the frames was coated with the obtained CNT dispersion liquid. Then, the CNT dispersion liquid used for coating was dried for 30 minutes at 50° C. and then for 30 minutes at 120° C., thereby obtaining a printing film. The obtained printing film was immersed in ethanol for 1 hour so as to remove the dispersant, and then peeled from the glass substrate, thereby obtaining a self-supported film. The self-supported film was dried for 30 minutes at 50° C. and then for 150 minutes at 120° C. The obtained self-supported film was pressed under 30 kN by using a roll press machine (manufactured by TESTER SANGYO CO., LTD.), thereby obtaining a thermoelectric conversion layer. The thermoelectric conversion layer was cut in a size of 1 cm×1 cm, thereby obtaining a sample for measurement.

### Examples 11 to 15 and 19

Samples for measurement of Examples 11 to 15 and 19 were prepared by the same method as that in Example 10 under the conditions described in Table 1.

### Comparative Example 1

A sample was prepared in the same manner as in Example 1, except that the 2-butanone solution containing 10 mM tetracyanoquinodimethane was changed to a 10 mM aqueous nitric acid solution.

### Comparative Example 2

A sample was prepared in the same manner as in Example 1, except that the 2-butanone solution containing 10 mM tetracyanoquinodimethane was changed to a methanol solution containing 10 mM trimethyl propyl ammonium bis(trifluoromethanesulfonyl)imide.

### Comparative Examples 3 to 11

Samples for measurement of Comparative Examples 3 to 11 were prepared by the same method as that in Example 2 under the conditions described in Table 1.

2. Evaluation 1 of Thermoelectric Conversion Performances of Thermoelectric Conversion Layers of Examples 1 to 21 and Comparative Examples 1 to 11

For each of the examples and the comparative examples, 10 thermoelectric conversion layers were prepared and used for the following evaluation.

(Electric Conductivity (σ) and Seebeck Coefficient (S))

By using a thermoelectric characteristic measuring apparatus MODEL RZ2001i (manufactured by OZAWA SCIENCE CO., LTD.), an electric conductivity and a Seebeck coefficient (thermoelectromotive force per absolute temperature of 1 K) of the thermoelectric conversion layer at about 80° C. and 105° C. were measured. By interpolation, an electric conductivity and a Seebeck coefficient at 100° C. were calculated. For one example (comparative example), 10 samples were measured, and the average thereof was used.

Each of the electric conductivity and the Seebeck coefficient was evaluated based on values normalized by the following equation.

(Electric Conductivity (σ))

By adopting Comparative Example 3 as a reference comparative example, a normalized electric conductivity of each of the examples and the comparative examples was determined by the following equation. The evaluation standards are as below. The results are shown in Table 1.

(Normalized electric conductivity)=(electric conductivity of thermoelectric conversion layer of each example or each comparative example)/(electric conductivity of thermoelectric conversion layer of Comparative Example 3)

<<Evaluation Standards>>

“A”: The normalized electric conductivity was equal to or higher than 7.0.

“B”: The normalized electric conductivity was equal to or higher than 4.0 and less than 7.0.

“C”: The normalized electric conductivity was equal to or higher than 1.5 and less than 4.0.

“D”: The normalized electric conductivity was equal to or higher than 0.9 and less than 1.5.

“E”: The normalized electric conductivity was less than 0.9,

(Seebeck Coefficient (S))

By adopting Comparative Example 3 as a reference comparative example, a normalized Seebeck coefficient of each of the examples and the comparative examples was determined by the following equation. The evaluation standards are as below. The results are shown in Table 1.

(Normalized Seebeck coefficient)=(Seebeck coefficient of thermoelectric conversion layer of each example or each comparative example)/(Seebeck coefficient of thermoelectric conversion layer of Comparative Example 3)

<<Evaluation Standards>>

“A”: The normalized Seebeck coefficient was equal to or higher than 1.2.

“B”: The normalized Seebeck coefficient was equal to or higher than 0.9 and less than 1.2.

“C”: The normalized Seebeck coefficient was equal to or higher than 0.6 and less than 0.9.

“D”: The normalized Seebeck coefficient was equal to or higher than 0.3 and less than 0.6.

“E”: The normalized Seebeck coefficient was less than 0.3.

<Evaluation of Power Factor Ratio (PF Ratio)>

First, by the following equation, a power factor of each of the examples and the comparative examples was calculated.

(Power factor) (electric conductivity)×(Seebeck coefficient)²

Then, by using the calculated power factor of each of the examples and the comparative examples, a normalized power factor ratio was calculated by the equation described below. Specifically, by the following equation, the power factor ratio of each of the examples and the comparative examples was calculated. For Examples I to 3 and 16 and Comparative Examples 1 to 3 and 9 to 11, Comparative Example 3 was used as a reference comparative example. For Examples 4 to 15 and 17 to 21 and Comparative Example 8, Comparative Example 8 was used as a reference comparative example. For Comparative Examples 4 and 5, Comparative Example 4 was used as a reference comparative example. For Comparative Examples 6 and 7, Comparative Example 6 was used as a reference comparative example. In this way, how much the power factor was improved by the dopant for CRIT with the same semiconductor ratio was evaluated. The results are shown in Table 1.

(Power factor ratio)=(power factor of thermoelectric conversion layer of each example or each comparative example)/(power factor of thermoelectric conversion layer of reference comparative example)

<Evaluation of Thermal Conductivity K and Figure of Merit Z Ratio>

(Evaluation of Figure of Merit Z Ratio)

The figure of merit Z was calculated by the following equation.

(Figure of merit Z)=[(electric conductivity)×(Seebeck coefficient)²]/thermal conductivity

For calculating the figure of merit Z, the thermal conductivity of the thermoelectric conversion layer of each of the examples and the comparative examples was calculated by the following equation. For determining the thermal diffusivity, the specific heat, and the density, similarly to the electric conductivity and the Seebeck coefficient, 10 samples were measured for each example (comparative example), and the average thereof was used.

(Thermal conductivity [W/mK])=(specific heat [J/kg·K])×(density [kg/m³])×(thermal diffusivity [m²/s])

“Specific heat” in the above equation was measured by differential scanning calorimetry (DSC method), and “density” was measured by mass/volume, “Thermal diffusivity” was measured using THERMOWAVE ANALYZER TA33 (manufactured by BETHEL Co., Ltd.),

By using the calculated figure of merit Z of each of the examples and the comparative examples, a normalized figure of merit Z ratio (hereinafter, referred to as “Z ratio” as well) was calculated by the equation shown below. Specifically, the Z ratio of each of the examples and the comparative examples was calculated by the following equation. For Examples 1 to 3 and 16 and Comparative Examples 1 to 3 and 9 to 11, Comparative Example 3 was used as a reference comparative example. For Examples 4 to 15 and 17 to 21 and Comparative Example 8, Comparative Example 8 was used as a reference comparative example. For Comparative Examples 4 and 5, Comparative Example 4 was used as a reference comparative example. For Comparative Examples 6 and 7, Comparative Example 6 was used as a reference comparative example. In this way, how much Z was improved by the dopant for CNT with the same semiconductor ratio was evaluated. The results are shown in Table 1.

(Zratio)=(figure of merit Z of thermoelectric conversion layer of each example or each comparative example)/(figure of merit Z of thermoelectric conversion layer of reference comparative example)

(Evaluation of Thermal Conductivity κ)

The thermal conductivity κ was evaluated based on the value normalized by the equation shown below. Specifically, by adopting Comparative Example 3 as a reference comparative example, a normalized thermal conductivity (hereinafter, referred to as “normalized thermal conductivity” as well) of each of the examples and the comparative examples was calculated by the following equation. The evaluation standards are as below. The results are shown in Table 1.

(Normalized thermal conductivity)=(thermal conductivity of thermoelectric conversion layer of each example or each comparative example)/(thermal conductivity of thermoelectric conversion layer of Comparative Example 3)

<<Evaluation Standards>>

“A”: The normalized thermal conductivity was less than 0.7.

“B”: The normalized thermal conductivity was equal to or higher than 0.7 and less than 0.9.

“C”: The normalized thermal conductivity was equal to or higher than 0.9 and less than 1.1.

“D”: The normalized thermal conductivity was equal to or higher than 1.1.

In Table 1, “Content/% by mass” in the column of Single-layer CNT, the column of Dopant, and the column of Binder means the content of each component with respect to the total mass of the thermoelectric conversion layer.

In Table 1, “Content with respect to CNT/% by mass” in the column of Dopant and the column of Binder means “content of dopant with respect to content of single-layer CNT” and “content of binder with respect to content of single-layer CNT”.

In Table 1, “Semiconductor ratio (%)” of the single-layer CNT means “number of molecules of semiconducting CNT/total number of molecules of single-layer CNT×100”, and measured by the absorption spectroscopy described above.

In Table 1, “G/D ratio” of the single-layer CNT means an intensity ratio (G/D) between a G-band and a D-band in a Raman spectrum (excitation wavelength: 532 nm).

In Table 1, “Oxidation-reduction potential (V)” of the dopant means an oxidation-reduction potential of the dopant with respect to a saturated calomel electrode. The measurement method thereof is as described above.

In Table 1, in the column of “Addition method”, “A” means that the thermoelectric conversion layer was formed by immersing the thermoelectric conversion layer precursor in a dopant solution, and “B” means that the thermoelectric conversion layer was formed using the composition for forming a thermoelectric conversion layer.

TABLE 1

| | Thermoelectric conversion layer | | | | | | | | | | | | | | | | | |
|---|---|---|---|---|---|---|---|---|---|---|---|---|---|---|---|---|---|---|
| | | | | | Dopant | | | | | Binder | | | | | | | | |
| | | | | | | | | Content | | | | Content | | | | | | |
| | | | | | | | | with | | | | with | | Thermoelectric | | | | |
| | Single-layer CNT | | | | | Oxidation- | | respect | | | | respect | | conversion | | | | |
| | Semiconductor | | | Content/ | | reduction | Content/ | to CNT/ | | | Content/ | to CNT/ | | performances | | | | |
| | ratio/ | | G/D | % by | | potential | % by | % by | Addition | | % by | % by | | | | PF | | Z |
| Table 1 | % | Calcination | ratio | mass | Structure | (V) | mass | mass | method | Type | mass | mass | Index A | σ | S | ratio | κ | ratio |
| Example 1 | 95 | Performed | 41 | 98.5 | 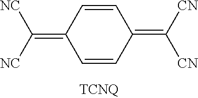 [SMILES: N#CC(C#N)=c1ccc(=C(C#N)C#N)cc1] | 0.15 | 1.5 | 1.6 | A | N/A | 0 | 0 | 3.94 | B | B | 6.3 | B | 7.1 |
| Example 2 | 95 | Performed | 41 | 98.2 | 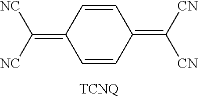 [SMILES: N#CC(C#N)=c1ccc(=C(C#N)C#N)cc1] | 0.15 | 1.8 | 1.8 | B | N/A | 0 | 0 | 3.94 | B | B | 6.1 | B | 7.9 |
| Example 3 | 95 | Performed | 41 | 97.5 | 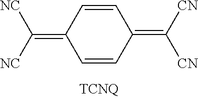 [SMILES: N#CC(C#N)=c1ccc(=C(C#N)C#N)cc1] | 0.15 | 2.5 | 2.6 | B | N/A | 0 | 0 | 3.93 | A | C | 6.6 | B | 8.2 |
| Example 4 | 98 | Performed | 40 | 98.4 | 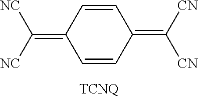 [SMILES: N#CC(C#N)=c1ccc(=C(C#N)C#N)cc1] | 0.15 | 1.6 | 1.6 | B | N/A | 0 | 0 | 3.96 | B | A | 8.9 | B | 10.8 |
| Example 5 | 98 | Performed | 40 | 98.9 | 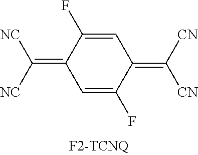 [SMILES: N#CC(C#N)=c1cc(F)c(=C(C#N)C#N)cc1F] | 0.3 | 1.1 | 1.1 | B | N/A | 0 | 0 | 4.03 | A | B | 9.1 | B | 11.2 |
| Example 6 | 98 | Performed | 40 | 99.1 | 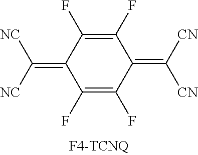 [SMILES: N#CC(C#N)=c1c(F)c(F)c(=C(C#N)C#N)c(F)c1F] | 0.52 | 0.9 | 0.9 | B | N/A | 0 | 0 | 412 | A | B | 9.3 | B | 11.6 |
| Example 7 | 98 | Performed | 40 | 99 | 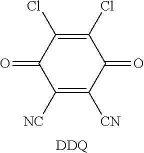 | 0.5 | 1 | 1.0 | B | N/A | 0 | 0 | 4.11 | A | B | 8.8 | B | 11.0 |
| Example 8 | 98 | Performed | 40 | 98.7 | 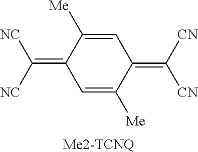 | 0.11 | 1.3 | 1.3 | B | N/A | 0 | 0 | 3.95 | B | A | 9.1 | B | 11.3 |
| Example 9 | 98 | Performed | 40 | 98.4 | 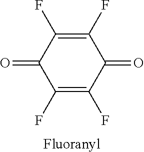 | 0.1 | 1.6 | 1.6 | B | N/A | 0 | 0 | 3.94 | B | A | 8.9 | B | 11.0 |
| Example 10 | 98 | Performed | 40 | 65.9 | 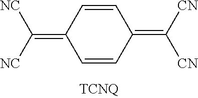 [SMILES: N#CC(C#N)=c1ccc(=C(C#N)C#N)cc1] | 0.15 | 1.1 | 1.7 | B | CMC—Na | 33 | 50 | 3.96 | B | A | 9.2 | A | 14.3 |
| Example 11 | 98 | Performed | 40 | 49.5 | 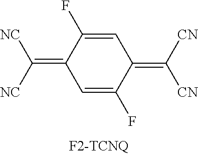 [SMILES: N#CC(C#N)=c1cc(F)c(=C(C#N)C#N)cc1F] | 0.3 | 1 | 2.0 | B | CMC—Na | 49.5 | 100 | 4.02 | B | B | 9.4 | A | 14.0 |
| Example 12 | 98 | Performed | 40 | 65.4 | 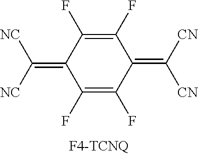 [SMILES: N#CC(C#N)=c1c(F)c(F)c(=C(C#N)C#N)c(F)c1F] | 0.52 | 1.9 | 2.9 | B | CMC—Na | 32.7 | 50 | 4.10 | A | B | 9.4 | A | 14.1 |
| Example 13 | 98 | Performed | 40 | 56 | 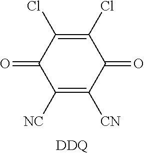 | 0.5 | 2.0 | 3.6 | B | CMC—Na | 42 | 75 | 4.08 | A | B | 9.0 | A | 13.7 |

TABLE 2

| | Thermoelectric conversion layer | | | | | | | | | | | | | | | | | |
|---|---|---|---|---|---|---|---|---|---|---|---|---|---|---|---|---|---|---|
| | | | | | Dopant | | | | | Binder | | | | | | | | |
| Con- | Single-layer CNT | | | | | | | Content with | | | | Content with | | Thermoelectric conversion | | | | |
| tinued | Semi- | | | Content/ | | Oxidation- | | respect | | | | respect | | performances | | | | |
| from | conductor | Calci- | G/D | % by | | reduction | Content/ | to CNT/ | Addition | | Content/ | to CNT/ | Index | | | PF | | Z |
| Table 1 | ratio/% | nation | ratio | mass | Structure | potential (V) | % by mass | % by mass | method | Type | % by mass | % by mass | A | σ | S | ratio | κ | ratio |
| Ex- ample 14 | 98 | Per- formed | 40 | 65.9 | 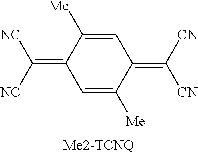 | 0.11 | 1.1 | 1.7 | B | CMC—Na | 33 | 50 | 3.95 | B | A | 9.2 | A | 14.3 |
| Ex- ample 15 | 98 | Per- formed | 40 | 82.5 | 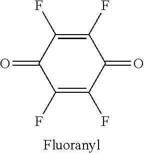 | 0.1 | 1.0 | 1.2 | B | CMC—Na | 16.5 | 20 | 3.95 | A | B | 9.0 | A | 13.9 |
| Ex- ample 16 | 95 | Per- formed | 40 | 98.5 | 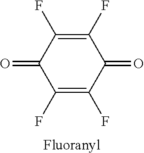 | 0.1 | 1.5 | 1.5 | B | N/A | 0 | 0 | 3.82 | B | C | 5.6 | B | 6.8 |
| Ex- ample 17 | 98 | Per- formed | 40 | 96.9 | 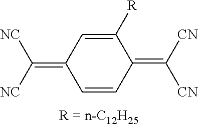 | 0.13 | 3.1 | 3.2 | B | N/A | 0 | 0 | 3.94 | B | A | 5.5 | B | 6.9 |
| Ex- ample 18 | 98 | Per- formed | 40 | 90.5 | 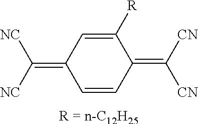 | 0.13 | 9.5 | 10.5 | B | N/A | 0 | 0 | 3.87 | B | B | 4.1 | B | 6.1 |
| Ex- ample 19 | 98 | Per- formed | 40 | 39.8 | 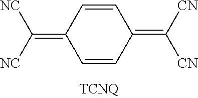 [SMILES: N#CC(C#N)=c1ccc(=C(C#N)C#N)cc1] | 0.15 | 0.6 | 1.5 | B | CMC—Na | 59.6 | 150 | 3.96 | C | A | 7.9 | A | 12.3 |
| Ex- ample 20 | 98 | Per- formed | 40 | 98 | 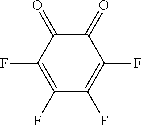 [SMILES: O=C1C(=O)C(F)=C(F)C(F)=C1F] | 0.1 | 2 | 2.0 | B | N/A | 0 | 0 | 3.94 | A | B | 8.7 | A | 13.1 |
| Ex- ample 21 | 98 | Per- formed | 40 | 66.7 | 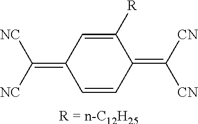 | 0.13 | 33.3 | 49.9 | B | N/A | 0 | 0 | 3.47 | A | C | 3.8 | B | 5.1 |

TABLE 3

| | Thermoelectric conversion layer | | | | | | | | | | | | | | | | | |
|---|---|---|---|---|---|---|---|---|---|---|---|---|---|---|---|---|---|---|
| | | | | | Dopant | | | | | Binder | | | | | | | | |
| | Single-layer CNT | | | | | | | Content | | | | Content | | | | | | |
| | Semi- | | | | | Oxidation- | | with | | | | with | | Thermoelectric conversion | | | | |
| Continued | conductor | | | Content/ | | reduction | | respect | | | | respect | | performances | | | | |
| from | ratio/ | Calci- | G/D | % by | | potential | Content/ | to CNT/ | Addition | | Content/ | to CNT/ | Index | | | PF | | Z |
| Table 1 | % | nation | ratio | mass | Structure | (V) | % by mass | % by mass | method | Type | % by mass | % by mass | A | σ | S | ratio | κ | ratio |
| Comparative | 95 | Per- | 41 | 98.5 | Nitric acid | — | 1.5 | 1.5 | A | N/A | 0 | 0 | — | C | C | 4.1 | D | 2.7 |
| Example 1 | | formed | | | | | | | | | | | | | | | | |
| Comparative Example 2 | 95 | Per- formed | 43 | 98.9 | 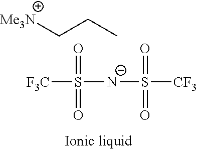 | — | 1.1 | 1.1 | A | N/A | 0 | 0 | — | D | B | 0.98 | D | 0.65 |
| Comparative | 95 | Per- | 41 | 100 | N/A | — | 0 | 0.0 | B | N/A | 0 | 0 | — | D | B | 1 | C | 1 |
| Example 3 | | formed | | | | | | | | | | | | | | | | |
| Comparative | 67 | Per- | 42 | 100 | N/A | — | 0 | 0.0 | B | N/A | 0 | 0 | — | C | D | 1 | D | 0.5 |
| Example 4 | | formed | | | | | | | | | | | | | | | | |
| Comparative Example 5 | 67 | Per- formed | 42 | 98.6 | 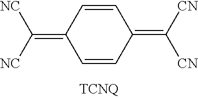 [SMILES: N#CC(C#N)=c1ccc(=C(C#N)C#N)cc1] | 0.15 | 1.4 | 1.4 | B | N/A | 0 | 0 | 2.86 | D | E | 1.9 | C | 1.7 |
| Comparative | 90 | Per- | 41 | 100 | N/A | — | 0 | 0.0 | B | N/A | 0 | 0 | — | D | C | 1 | C | 1 |
| Example 6 | | formed | | | | | | | | | | | | | | | | |
| Comparative Example 7 | 90 | Per- formed | 41 | 98.7 | 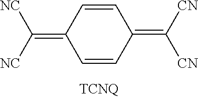 [SMILES: N#CC(C#N)=c1ccc(=C(C#N)C#N)cc1] | 0.15 | 1.3 | 1.3 | B | N/A | 0 | 0 | 3.74 | C | D | 2.2 | B | 2.8 |
| Comparative | 98 | Per- | 40 | 98.5 | N/A | — | 1.5 | 1.5 | B | N/A | 0 | 0 | — | E | A | 1 | C | 1 |
| Example 8 | | formed | | | | | | | | | | | | | | | | |
| Comparative Example 9 | 95 | N/A | 34 | 98.5 | 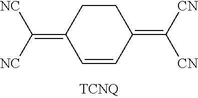 [SMILES: N#CC(C#N)=C1C=CC(=C(C#N)C#N)CC1] | 0.15 | 1.5 | 1.5 | B | N/A | 0 | 0 | 3.27 | C | C | 2.6 | B | 3.3 |
| Comparative Example 10 | 95 | Per- formed | 41 | 96 | 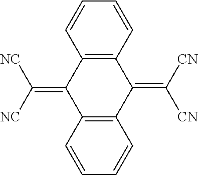 [SMILES: N#CC(C#N)=c1c2ccccc2c(=C(C#N)C#N)c2ccccc12] | −0.36 | 4 | 4.2 | B | N/A | 0 | 0 | 3.71 | D | B | 1.1 | B | 1.4 |
| Comparative Example 11 | 95 | Per- formed | 41 | 95.5 | 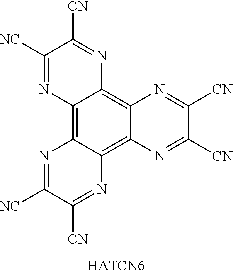 [SMILES: N#Cc1nc2c3nc(C#N)c(C#N)nc3c3nc(C#N)c(C#N)nc3c2nc1C#N] | −0.01 | 4.5 | 4.7 | B | N/A | 0 | 0 | 3.84 | E | A | 0.9 | B | 1.1 |

As is evident from the results shown in Table 1, the power factor and the figure of merit Z of the thermoelectric conversion layer according to the embodiment of the present invention are markedly excellent.

Through the comparison of CNT with a semiconductor content of 95% of Examples 1 to 3 and 16 and Comparative Examples 1 to 3, 9, and 10, it has been confirmed that the power factor and the figure of merit Z of Examples 1 to 3 are significantly improved compared to those of Comparative Example 3 (comparative example in which the single-layer CNT was doped with oxygen) as a reference comparative example. Furthermore, through the comparison of CNT with a semiconductor content of 98% of Examples 4 to 15 and 17 to 21 and Comparative Example 8, the same result has been confirmed. It has been confirmed that in a case where the specific dopant shown in Examples 1 to 21 is added to CNT, as an unexpected effect, it is possible to reduce the thermal conductivity K while improving the electric conductivity a, Presumably, because the dopant is inserted into the point of contact between the CNT bundles, phonon scattering may be accelerated while CNT are being doped, and hence the above effect may be obtained.

Through the comparison between Comparative Example 4 and Comparative Example 5 and the comparison between Comparative Example 6 and Comparative Example 7, it is has been confirmed that in a case where the semiconductor ratio of the single-layer CNT is less than 95%, even though the G/D ratio of the single-layer CNT was set to be equal to or higher than 40 and an organic dopant having a non-onium salt structure that has an oxidation-reduction potential equal to or higher than 0 V is used, the power factor and the figure of merit Z are slightly improved.

Through the comparison between Examples 4 and 10, Examples 5 and 11, Examples 6 and 12, Examples 7 and 13, Examples 8 and 14, and Examples 9 and 15, it has been confirmed that in a case where the thermoelectric conversion layer contains a non-conjugated polymer as a binder (preferably in a case where the thermoelectric conversion layer contains a hydrogen bonding resin), the thermal conductivity can be further reduced, and consequently, the figure of merit Z is significantly improved.

Through the comparison of Examples 10 to 15 and Example 19, it has been confirmed that in a case where the content of the binder is 5% to 100% by mass with respect to the total mass of the specific single-layer CNT, the electric conductivity a tends to become excellent, and consequently, the power factor and the figure of merit Z can be further improved.

Through the comparison between Example 18 and Example 21, it has been confirmed that in a case where the index A is equal to or higher than 3.5, the figure of merit Z is further improved. Particularly, through the comparison of Examples 2 to 21 in which the dopant was added by the same method, it has been confirmed that in a case where the index A is equal to or higher than 3.9, the figure of merit Z is further improved.

### 3. Evaluation 2 of Thermoelectric Conversion Performances of Thermoelectric Conversion Layer of Examples 1 to 21 and Comparative Examples 1 to 3, 4, 6, and 8

<Evaluation of Variation Resulting from Figure of Merit Z>

For 10 thermoelectric conversion layers of each of the examples and the comparative examples, the figure of merit Z was calculated by the method described above, and evaluation was performed based on the following evaluation standards.

Variation (maximum change rate of figure of merit Z)=(maximum figure of merit Z−minimum figure of merit Z)/(maximum figure of merit Z)

<<Evaluation Standards>>

“A”: The variation was less than 0.05.

“B”: The variation was equal to or greater than 0.05 and less than 0.1.

“C”: The variation was equal to or greater than 0.1.

<Evaluation of Temporal Stability of Thermoelectric Conversion Performances>

Ten thermoelectric conversion layers prepared for each of the examples and the comparative examples were measured immediately after they were prepared and 1 month after they were prepared, and the figure of merit Z was calculated. By using the average of the figure of merit Z, a retention rate of the figure of merit Z was calculated by the following equation, and the temporal stability of the thermoelectric conversion layer was evaluated.

(Z retention rate)=(average figure of merit Z calculated after one month from preparation)/(average figure of merit Z calculated immediately after preparation)

<<Evaluation Standards>>

“A”: The Z retention rate was equal to or higher than 0.85,

“B”: The Z retention rate was equal to or higher than 0.7 and less than 0.85.

“C”: The Z retention rate was less than 0.7.

The results are shown in Table 2.

TABLE 4

| | Example 1 | Example 2 | Example 3 | Example 4 | Example 5 | Example 6 | Example 7 | Example 8 |
|---|---|---|---|---|---|---|---|---|
| Variation | A | A | A | A | A | A | A | A |
| Temporal | A | A | A | A | A | A | A | A |
| stability | | | | | | | | |

| | Example 9 | Example 10 | Example 11 | Example 12 | Example 13 | Example 14 |
|---|---|---|---|---|---|---|
| Variation | A | A | A | A | A | A |
| Temporal | A | A | A | A | A | A |
| stability | | | | | | |

TABLE 5

| | Example | Example | Example | Example | Example | Example | Example | Comparative |
|---|---|---|---|---|---|---|---|---|
| | 15 | 16 | 17 | 18 | 19 | 20 | 21 | Example 1 |
| Variation | A | A | A | A | A | A | A | C |
| Temporal | A | A | A | A | A | A | A | C |
| stability | | | | | | | | |

| | Comparative | Comparative | Comparative | Comparative | Comparative |
|---|---|---|---|---|---|
| | Example 2 | Example 3 | Example 4 | Example 6 | Example 8 |
| Variation | B | C | C | C | C |
| Temporal | B | C | C | C | C |
| stability | | | | | |

From the results shown in Table 2, it has been confirmed that the thermoelectric conversion layer according to the embodiment of the present invention results in a small variation of the figure of merit Z and has excellent temporal stability.

### (Example 22) Preparation of Thermoelectric Conversion Module

Sixteen p-type thermoelectric conversion layers were prepared in the same manner as in Example 1, except that buckypaper was cut in a size of 4 mm x 8 mm.

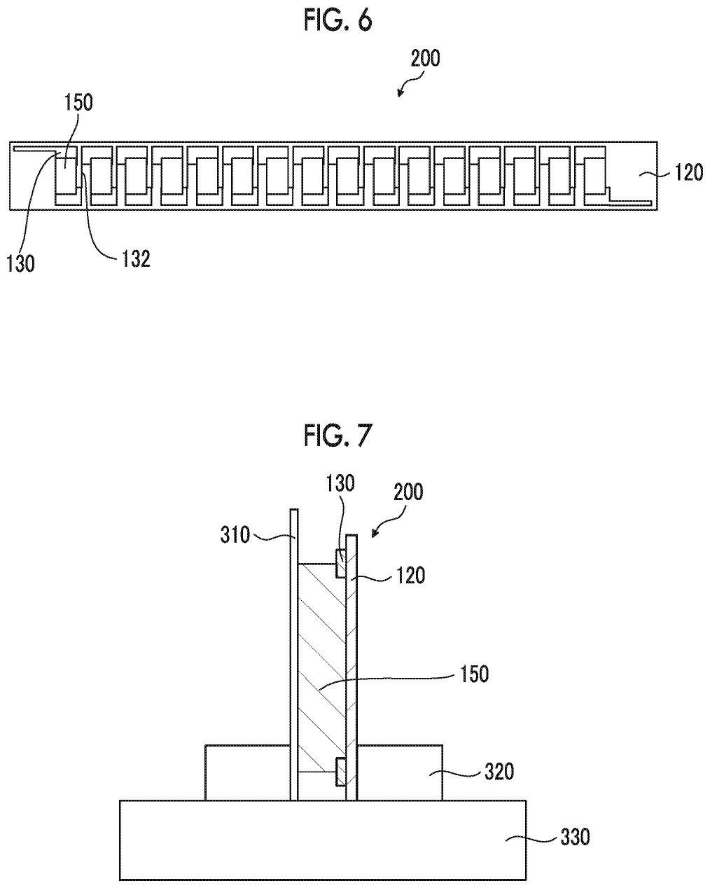

Then, by using the thermoelectric conversion layers, the thermoelectric conversion module shown in FIG. 6 was prepared.

First, a silver paste was printed on a 1.6 cm (width)×14 cm (length) substrate 120 (polyimide substrate) by screen printing, the printed material of the silver paste was dried for 1 hour at 120° C., and 16 pairs of electrodes 130 and wiring 132 were simultaneously formed. The size of one electrode was 4 mm (width)×2.5 mm (length), and an interelectrode distance was 5 mm. Furthermore, in order that sixteen thermoelectric conversion layers 150, which will he described later, were connected to each other in series, a pair of electrodes 130 were connected to each other through wiring having a width of 1 mm.

Then, the thermoelectric conversion layer cut in a size of 4 mm (width)×8 mm (length) was interposed between and bonded to the electrodes by using a double-sided tape. The portions in which the electrodes and the thermoelectric conversion layer contacted each other were coated with a silver paste, and the silver paste was dried for 1 hour at 120° C. such that the electrodes and the thermoelectric conversion layer were bonded and electrically connected to each other. A thermoelectric conversion module 200 obtained in this way was used as a thermoelectric conversion module of Example 22.

### Comparative Example 12

A thermoelectric conversion module was prepared in the same manner as in Example 22, except that the thermoelectric conversion layer of Comparative Example 1 that was cut in a size of 4 mm x 8 mm was used as a thermoelectric conversion layer.

### Comparative Example 13

A thermoelectric conversion module was prepared in the same manner as in Example 22, except that the thermoelectric conversion layer of Comparative Example 2 that was cut in a size of 4 mm×8 mm was used as a thermoelectric conversion layer.

(Evaluation of Thermoelectric Conversion Module)

FIG. 7 is a view for illustrating a method for evaluating the thermoelectric conversion modules in examples. As shown in FIG. 7, a power generating layer side of the thermoelectric conversion module 200 was protected with an aramid film 310. Furthermore, the lower portion of the thermoelectric conversion module 200 was fixed by being interposed between copper plates 320 installed on a hot plate 330 such that the lower portion of the thermoelectric conversion module 200 could be efficiently heated.

Then, terminals (not shown in the drawing) of a source meter (manufactured by Keithley Instruments, Inc.) were mounted on extraction electrodes (not shown in the drawing) at both ends of the thermoelectric conversion module 200, and the temperature of the hot plate 330 was caused to remain constant at 100° C. such that a temperature difference was caused in the thermoelectric conversion module 200.

The current-voltage characteristics were measured, and a short-circuit current and an open voltage were measured. From the measured results, an output was calculated by “(Output)=[(Current)×(Voltage)/4]”. As a result, the output was Example 22>Comparative Example 12>Comparative Example 13, which supports the performances of the thermoelectric conversion layer of Example 22.

### EXPLANATION OF REFERENCES

110, 120, 130, 140: thermoelectric conversion element

11, 17: metal plate

12, 22: first substrate

13, 23: first electrode

14, 24: thermoelectric conversion layer

15, 25: second electrode

16, 26: second substrate

30: second substrate

32: first substrate

32a, 30a: low thermal conduction portion

32b, 30b: high thermal conduction portion

34: thermoelectric conversion layer

36: first electrode

38: second electrode

41: n-type thermoelectric conversion layer

42: p-type thermoelectric conversion layer

43: lower substrate

44: second electrode

45: first and third electrodes

45A: first electrode

45B: third electrode

46: upper substrate

47: electron

48: hole

120: substrate

130: electrode

132: wiring

150: thermoelectric conversion layer

200: thermoelectric conversion module

310: aramid film

320: copper plate

330: hot plate

What is claimed is:

1. A thermoelectric conversion layer comprising:
single-layer carbon nanotubes; and
a dopant,
wherein the single-layer carbon nanotubes contain semiconducting single-layer carbon nanotubes at a ratio equal to or higher than 95% and have a G/D ratio equal to or higher than 40, and
the dopant is an organic dopant having a non-onium salt structure and has an oxidation-reduction potential equal to or higher than 0 V with respect to a saturated calomel electrode.

2. The thermoelectric conversion layer according to claim 1,
wherein the dopant is a compound having a quinoid structure.

3. The thermoelectric conversion layer according to claim 1,
wherein the dopant is a compound represented by Formula (1) or Formula (2) or a compound partially having a structure represented by Formula (1) or Formula (2), 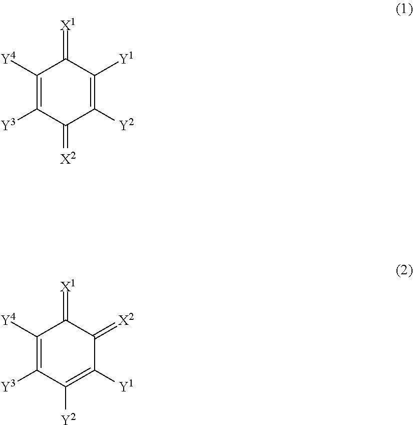
in Formulae (1) and (2), X¹ and X² each independently represent an oxygen atom, a sulfur atom, a group represented by *═C(CN)₂, a group represented by *═C(C(═O)R¹)₂, a group represented by *═C(CN)(C(═O)R¹), a group represented by *═C(CN)(CO₂R¹), a group represented by *═C(CO₂R¹)₂, a group represented by *═C(SO₂R¹)₂, or a group represented by *═C(CN)(SO₂R¹), R¹ represents a monovalent substituent, * represents a binding position, and Y¹ to Y⁴ each independently represent a hydrogen atom or a monovalent substituent.

4. The thermoelectric conversion layer according to claim 1,
wherein a content of the single-layer carbon nanotubes is equal to or greater than 20% by mass with respect to a total mass of the thermoelectric conversion layer.

5. The thermoelectric conversion layer according to claim 1,
wherein a content of the dopant is 0.01% to 10% by mass with respect to a total mass of the single-layer carbon nanotubes.

6. The thermoelectric conversion layer according to claim 1, further comprising:
a binder.

7. The thermoelectric conversion layer according to claim 6,
wherein at least one kind of the binder is a non-conjugated polymer.

8. The thermoelectric conversion layer according to claim 6,
wherein a content of the binder is 5% to 100% by mass with respect to the total mass of the single-layer carbon nanotubes.

9. The thermoelectric conversion layer according to claim 6,
wherein the content of the binder is 20% to 100% by mass with respect to the total mass of the single-layer carbon nanotubes.

10. The thermoelectric conversion layer according to claim 1,
wherein an index A represented by Equation (1) is 3.5 to 21,
index A=[{T1+(P×10)}×T2/1,000]−(T3×0.01) Equation (1)
in Equation (1), T1 represents a ratio (%) of the semiconducting single-layer carbon nanotubes contained in the single-layer carbon nanotubes, T2 represents a G/D ratio of the single-layer carbon nanotubes, T3 represents a content (% by mass) of the dopant with respect to the single-layer carbon nanotubes, and P represents an oxidation-reduction potential (V) of the dopant with respect to the saturated calomel electrode.

11. A composition for forming a thermoelectric conversion layer comprising:
single-layer carbon nanotubes; and
a dopant,
wherein the single-layer carbon nanotubes contain semiconducting single-layer carbon nanotubes at a ratio equal to or higher than 95% and has a G/D ratio equal to or higher than 40, and
the dopant is an organic dopant having a non-onium salt structure and has an oxidation-reduction potential equal to or higher than 0 V with respect to a saturated calomel electrode.

12. A thermoelectric conversion element comprising:
the thermoelectric conversion layer according claim 1

13. A thermoelectric conversion module comprising:
a plurality of thermoelectric conversion elements according to claim 12.

14. The thermoelectric conversion layer according to claim 2,
wherein the dopant is a compound represented by Formula (1) or Formula (2) or a compound partially having a structure represented by Formula (1) or Formula (2), 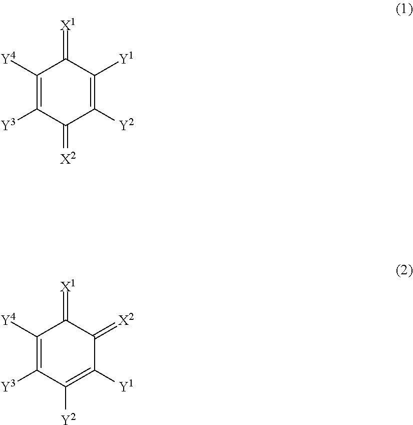
in Formulae (1) and (2), X¹ and X² each independently represent an oxygen atom, a sulfur atom, a group represented by *═C(CN)₂, a group represented by *═C(C(═O)R¹)₂, a group represented by *═C(CN)(C(═O)R¹), a group represented by *═C(CN)(CO₂R¹), a group represented by *═C(CO₂R¹)₂, a group represented by *═C(SO₂R¹)₂, or a group represented by *═C(CN)(SO₂R¹), R¹ represents a monovalent substituent, * represents a binding position, and Y¹ to Y⁴ each independently represent a hydrogen atom or a monovalent substituent.

15. The thermoelectric conversion layer according to claim 2,
wherein a content of the single-layer carbon nanotubes is equal to or greater than 20% by mass with respect to a total mass of the thermoelectric conversion layer.

16. The thermoelectric conversion layer according to claim 3,
wherein a content of the single-layer carbon nanotubes is equal to or greater than 20% by mass with respect to a total mass of the thermoelectric conversion layer.

17. The thermoelectric conversion layer according to claim 2,
wherein a content of the dopant is 0.01% to 10% by mass with respect to a total mass of the single-layer carbon nanotubes.

18. The thermoelectric conversion layer according to claim 3,
wherein a content of the dopant is 0.01% to 10% by mass with respect to a total mass of the single-layer carbon nanotubes.

19. The thermoelectric conversion layer according to claim 4,
wherein a content of the dopant is 0.01% to 10% by mass with respect to a total mass of the single-layer carbon nanotubes.

20. The thermoelectric conversion layer according to claim 2, further comprising:
a binder.
